(19) United States
(12) Patent Application Publication
(10) Pub. No.: US 2015/0318516 A1
(43) Pub. Date: Nov. 5, 2015

(54) ORGANIC EL LIGHT-EMITTING DEVICE AND ILLUMINATION DEVICE

(71) Applicant: PANASONIC INTELLECTUAL PROPERTY MANAGEMENT CO., LTD., Osaka-shi, Osaka (JP)

(72) Inventors: Norihiro ITO, Osaka (JP); Tetsuo ISHIDA, Hyogo (JP); Kazuya HASEGAWA, Osaka (JP)

(73) Assignee: PANASONIC INTELLECTUAL PROPERTY MANAGEMENT CO., LTD., Osaka-shi, Osaka (JP)

(21) Appl. No.: 14/651,805

(22) PCT Filed: Dec. 13, 2013
(86) PCT No.: PCT/JP2013/007353

§ 371 Date: Jun. 12, 2015

(30) Foreign Application Priority Data
Dec. 13, 2012 (JP) 2012-272185
Feb. 13, 2013 (JP) 2013-025252

(51) Int. Cl. H01L 51/52; F21K 99/00

(52) U.S. Cl. CPC H01L 51/5256; F21K 9/30; H01L 51/524; H01L 2251/5361

(57) ABSTRACT

The organic EL light-emitting device according to the present invention includes a first substrate, an organic EL element, a second substrate and a sealing member. The organic EL light-emitting device further includes a protection layer, a hygroscopic member, a moisture permeable member, and a contact prevention member within a space enclosed by the first substrate, the second substrate and the sealing member. The hygroscopic member is for absorbing moisture within the space. The moisture permeable member is in contact with the hygroscopic member and allows moisture within the space to permeate.

### TECHNICAL FIELD

The present invention relates to an organic EL light-emitting device including an organic electroluminescence element (hereinafter referred to as “organic EL element”), and an illumination device including the organic EL light-emitting device.

### BACKGROUND ART

An organic EL light-emitting device includes a substrate, and an organic EL element which is placed on the substrate and includes electrodes and an organic layer. A light-emitting property of such an organic EL element may be deteriorated by moisture such as vapor, and therefore when the organic EL light-emitting device has been used for a long time, part thereof damaged by moisture may fail to produce luminescence. Such non-illuminous part is called as a dark spot, and such a dark spot may grow with time. Therefore, in order to suppress occurrence and growth of the dark spot, suppression of intrusion of moisture into the organic EL light-emitting device and removal of intruding moisture may be conducted by use of various methods.

For example, in document 1, as shown in FIG. 13, an organic EL light-emitting device 100 is formed by placing an organic EL element 400 on a first substrate 200, placing a resin composition 500 having moisture resistance so as to cover a whole surface of the organic EL element 400 and thereafter bonding a flat-plate-shaped second substrate 300 thereon. The resin composition 500 situated in the organic EL light-emitting device 100 prevents intrusion of moisture from outside. However, in this structure, it is difficult to completely block intrusion of moisture, and moisture intruding into the resin composition 500 may reach the organic EL element 400 and consequently shorten a lifetime of the organic EL element 400.

Thus, there has been also proposed a structure in which an organic EL element is covered with an inorganic seal film made of metal oxide or the like in addition to filling of a resin composition, in order to prevent intrusion of moisture.

### PRIOR TECHNICAL DOCUMENT

### Patent Document

[Document 1] JP H5-182759 A

### SUMMARY OF INVENTION

### Technical Problem

However, an inorganic film is likely to cause troubles such as peeling and cracking, and moisture may intrude mainly through part damaged by the peeling, the cracking or the like.

In view of the above insufficiency, the present invention has aimed to propose an organic EL light-emitting device capable of preventing intrusion of moisture into an organic EL element effectively and maintaining a stable light-emitting property for a long period, and an illumination device including the organic EL light-emitting device.

### Solution to Problem

The organic EL light-emitting device of the first feature in accordance with the present invention includes:
a first substrate;
an organic EL element disposed on the first substrate;
a second substrate disposed so as to face the first substrate with the organic EL element in-between; and
a sealing member disposed between the first substrate and the second substrate so as to surround the organic EL element, and
further comprises a protection layer, a hygroscopic member, a moisture permeable member, and a contact prevention member which are disposed within a space enclosed by the first substrate, the second substrate and the sealing member,
the protection layer covering a whole outer surface of the organic EL element,
the hygroscopic member configured to absorb moisture within the space,
the moisture permeable member being in contact with the hygroscopic member and allowing moisture within the space to permeate, and
the contact prevention member configured to prevent contact between the organic EL element and the second substrate.

The organic EL light-emitting device of the second feature in accordance with the present invention, realized in combination with the first feature, further includes a filling layer disposed within the space,
the filling layer including the contact prevention member and the moisture permeable member, and
the moisture permeable member being formed inside the filling layer to have at least one exposed surface facing the sealing member.

In the organic EL light-emitting device of the third feature in accordance with the present invention, realized in combination with the second feature, the moisture permeable member has a plurality of the exposed surface.

In the organic EL light-emitting device of the fourth feature in accordance with the present invention, realized in combination with the second or third feature, the moisture permeable member is a void formed inside the filling layer.

In the organic EL light-emitting device of the fifth feature in accordance with the present invention, realized in combination with the second or third feature, the moisture permeable member is made of material having moisture permeability.

In the organic EL light-emitting device of the sixth feature in accordance with the present invention, realized in combination with any one of the second to fifth features, the hygroscopic member is disposed inside the moisture permeable member.

In the organic EL light-emitting device of the seventh feature in accordance with the present invention, realized in combination with any one of the second to sixth features, the contact prevention member contains hygroscopic material so as to double as the hygroscopic member.

In the organic EL light-emitting device of the eighth feature in accordance with the present invention, realized in combination with any one of the second to seventh features, the filling layer has a sea-island structure in which the moisture permeable member and the contact prevention member are arranged so that the moisture permeable member and the contact prevention member resemble sea and an island respectively in a plan view of the filling layer.

In the organic EL light-emitting device of the ninth feature in accordance with the present invention, realized in combination with any one of the first to eighth features, the protection layer becomes thicker toward a periphery than at a center of the organic EL element in a plan view of the organic EL element.

In the organic EL light-emitting device of the tenth feature in accordance with the present invention, realized in combination with any one of the first to ninth features, the protection layer contains hygroscopic material so as to double as the hygroscopic member.

In the organic EL light-emitting device of the eleventh feature in accordance with the present invention, realized in combination with the first feature, the hygroscopic member is made of powder having a hygroscopic property.

In the organic EL light-emitting device of the twelfth feature in accordance with the present invention, realized in combination with the first feature, the hygroscopic member is made of solid hygroscopic material having a hygroscopic property.

In the organic EL light-emitting device of the thirteenth feature in accordance with the present invention, realized in combination with the first, eleventh or twelfth feature, the moisture permeable member is an empty space formed in the space.

In the organic EL light-emitting device of the fourteenth feature in accordance with the present invention, realized in combination with the first, eleventh, twelfth or thirteenth feature, the moisture permeable member is made of material having moisture permeability.

In the organic EL light-emitting device of the fifteenth feature in accordance with the present invention, realized in combination with the fourteenth feature, the hygroscopic member is covered with the moisture permeable member, and the organic EL light-emitting device further comprises an inorganic film covering the moisture permeable member.

In the organic EL light-emitting device of the sixteenth feature in accordance with the present invention, realized in combination with any one of the first to fifteenth features, the contact prevention member is made of material same as material of the sealing member.

In the organic EL light-emitting device of the seventeenth feature in accordance with the present invention, realized in combination with any one of the first to sixteenth features, the organic EL element includes an electrode facing the second substrate, and the contact prevention member is conductive and is in contact with the electrode.

The organic EL light-emitting device of the eighteenth feature in accordance with the present invention, realized in combination with the seventeenth feature, further includes a conductive layer disposed on a surface of the second substrate facing the first substrate, the contact prevention member being in contact with the conductive layer so as to electrically interconnect the electrode and the conductive layer.

The organic EL light-emitting device of the nineteenth feature in accordance with the present invention, realized in combination with any one of the first to eighteenth features, includes an inorganic film covering the organic EL element, the inorganic film being positioned between the organic EL element and the protection layer.

The illumination device in accordance with the present invention includes the organic EL light-emitting device according to any one of the first to nineteenth features and a device body to hold the organic EL light-emitting device.

### Advantageous Effects of Invention

In the organic EL light-emitting device according to the present invention, even when moisture intrudes into a space enclosed by a first substrate, a second substrate and a sealing member, such moisture is absorbed by a hygroscopic member. Therefore, it is possible to improve an effect of preventing intrusion of moisture into an organic EL element. Further, a moisture permeable member disposed in the space diffuses moisture, and thereby it is possible to prevent intensive intrusion of moisture from one direction. Thereby, the whole hygroscopic member can evenly absorb moisture. Accordingly, moisture is effectively absorbed by the hygroscopic member and thereby it is possible to further improve the effect of preventing intrusion of moisture into the organic EL element.

### BRIEF DESCRIPTION OF THE DRAWINGS

FIG. 1 is a sectional view illustrating structure of the organic EL light-emitting device according to the first embodiment of the present invention.

FIG. 2 is a sectional view illustrating structure of the organic EL light-emitting device according to the second embodiment of the present invention.

FIG. 3A is a sectional view illustrating the structure of the organic EL light-emitting device according to the third embodiment of the present invention, and FIG. 3B is a sectional view illustrating the structure of a modified example of the organic EL light-emitting device according to the third embodiment.

FIG. 4A is a sectional view illustrating the structure of the organic EL light-emitting device according to the fourth embodiment of the present invention, and FIG. 4B is a sectional view illustrating the structure of a modified example of the organic EL light-emitting device according to the fourth embodiment.

FIG. 5A is a sectional view illustrating the structure of the organic EL light-emitting device according to the fifth embodiment of the present invention, and FIG. 5B is a sectional view illustrating the structure of a modified example of the organic EL light-emitting device according to the fifth embodiment.

FIG. 6A is a sectional view illustrating the structure of the organic EL light-emitting device according to the sixth embodiment of the present invention, and FIG. 6B is a sectional view illustrating the structure of a modified example of the organic EL light-emitting device according to the sixth embodiment.

FIG. 7 is a sectional view illustrating the structure of the organic EL light-emitting device according to the sixth embodiment, which is different from the sectional view of FIG. 6A.

FIG. 8 is a sectional view illustrating the structure of the first modified example of the organic EL light-emitting device according to the sixth embodiment.

FIG. 9 is a sectional view illustrating the structure of the second modified example of the organic EL light-emitting device according to the sixth embodiment.

FIG. 10 is a sectional view illustrating the structure of the third modified example of the organic EL light-emitting device according to the sixth embodiment.

FIG. 11 is a partial sectional view illustrating the organic EL light-emitting device according to the sixth embodiment.

FIG. 12 is a sectional view illustrating the illumination device according to the embodiment of the present invention.

FIG. 13 is a sectional view illustrating the conventional example.

### DESCRIPTION OF EMBODIMENTS

An organic EL light-emitting device 1a according to the present embodiment includes a first substrate 2a, an organic electroluminescence element 4a (organic light-emitting diode; hereinafter, referred to as “organic EL element 4a”), a second substrate 3a and a sealing member 5a. The organic EL element 4a is disposed on the first substrate 2a. The second substrate 3a is disposed so as to face the first substrate 2a with the organic EL element 4a in-between. The sealing member 5a is disposed between the first substrate 2a and the second substrate 3a so as to surround the organic EL element 4a. The organic EL light-emitting device 1a further includes a protection layer 40a, a hygroscopic member 10a, a moisture permeable member 20a and a contact prevention member 30a within a space 11a enclosed by the first substrate 2a, the second substrate 3a and the sealing member 5a. The protection layer 40a covers a whole outer surface of the organic EL element 4a. The hygroscopic member 10a is configured to absorb moisture within the space S. The moisture permeable member 20a is in contact with the hygroscopic member 10a and is configured to allow vapor within the space 11a to permeate. The contact prevention member 30a is configured to prevent contact between the organic EL element 4a and the second substrate 3a. Note that the space 11a is defined as a three-dimensional region enclosed by the first substrate 2a, the second substrate 3a and the sealing member 5a, and a part or a whole of the space 11a may be occupied by various members and/or gas.

In the organic EL light-emitting device 1a, even when vapor intrudes into the space 11a enclosed by the first substrate 2a, the second substrate 3a and the sealing member 5a, such vapor is absorbed by the hygroscopic member 10a. Therefore, it is possible to improve an effect of preventing intrusion of moisture into the organic EL element 4a. Further, the moisture permeable member 20a disposed in the space 11a diffuses vapor, and thereby it is possible to prevent intensive intrusion of vapor from one direction. Thereby the whole hygroscopic member 10a can evenly absorb vapor. Accordingly, vapor is effectively absorbed by the hygroscopic member 10a, and thereby it is possible to further improve the effect of preventing intrusion of moisture into the organic EL element 4a.

In the present embodiment, the hygroscopic member 10a may be made of powdery hygroscopic material having a hygroscopic property.

In this case, a surface area of each of powder particles constituting the powdery hygroscopic material may be set to any size, and therefore it is easy to make the hygroscopic member 10a having a high hygroscopic property. Further, when the powdery hygroscopic material is activated under an inert gas atmosphere or in a vacuum, moisture absorption rate of the powdery hygroscopic material is improved. Therefore, the hygroscopic member 10a made of the powdery hygroscopic material can achieve an improvement of absorption efficiency of vapor.

In the present embodiment, it is preferable that the hygroscopic member 10a be made of a solid hygroscopic material 6a having a hygroscopic property.

In this case, the solid hygroscopic material 6a can cover the whole organic EL element 4a evenly and precisely.

In the present embodiment, it is preferable that the moisture permeable member 20a be an empty space 8a formed in the space 11a.

In this case, it is possible to evenly diffuse, within the space 11a, vapor intruding through the sealing member 5a.

In the present embodiment, it is preferable that the moisture permeable member 20a be made of a moisture permeable material 9 having moisture permeability.

In this case, whole strength of the organic EL light-emitting device 1a is increased, and therefore even when external force is applied to the organic EL light-emitting device 1a, the second substrate 3a is unlikely to bend. Thereby, it is possible to prevent contact between the organic EL element 4a and the second substrate 3a so as to suppress damage of the organic EL element 4a.

In the present embodiment, it is preferable that a whole outer surface of the hygroscopic member 10a be covered with the moisture permeable member 20a, and an inorganic film covering a whole outer surface of the moisture permeable member 20a is further included. In this structure, it is preferable that the moisture permeable member 20a be solid.

In this structure, the inorganic film is placed on the moisture permeable member 20a and therefore vapor is unlikely to intrude into the space 11a enclosed by the first substrate 2a, the second substrate 3a and the sealing member 5a owing to presence of the inorganic film. Accordingly, it is possible to further improve the effect of preventing intrusion of moisture into the organic EL element 4a.

In the present embodiment, it is also preferable that an inorganic film 51a covering the organic EL element 4a be positioned between the organic EL element 4a and the protection layer 40a. In this structure, intrusion of moisture into the organic EL element 4a is further suppressed, and accordingly sealing performance is improved.

In the present embodiment, it is preferable that the contact prevention member 30a be made of material same as material of the sealing member 5a.

In this case, the contact prevention member 30a made of material having high moisture permeation resistance is disposed in the space 11a enclosed by the first substrate 2a, the second substrate 3a and the sealing member 5a, and therefore it is possible to further improve the effect of preventing intrusion of moisture into the organic EL element 4a.

The following explanations are made to more specific embodiments of the present invention.

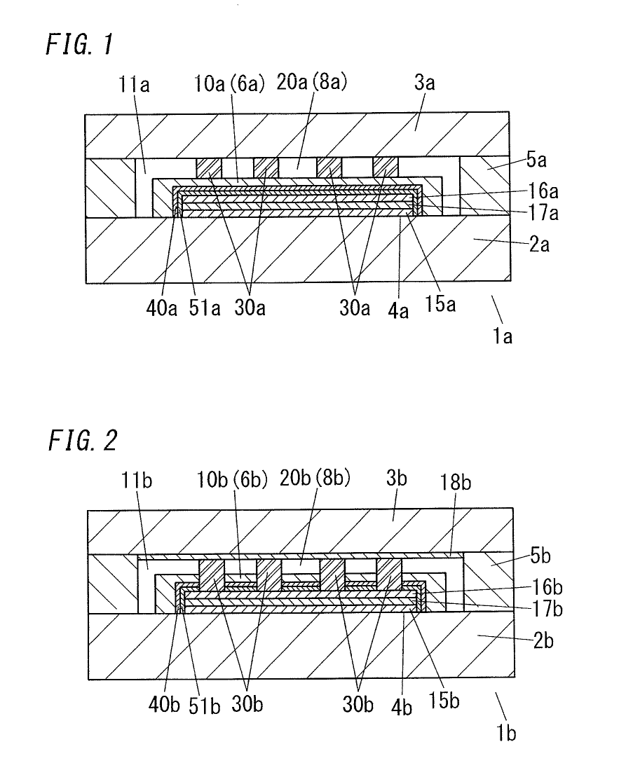

FIG. 1 shows the organic EL light-emitting device 1a according to the first embodiment.

In the present embodiment, the first substrate 2a is formed into a quadrangular plate shape in a plan view. Note that the plan view is defined as a view of the organic EL light-emitting device 1a viewed in such a direction that the first substrate 2a and the second substrate 3a face each other.

It is preferable that the first substrate 2a have a light transmissive property. The first substrate 2a may be colorless or colored. The first substrate 2a may be transparent or translucent. Material of the first substrate 2a may be publicly known material having strength enough to bear the organic EL element 4a, a light transmissive property or the like. Examples of the first substrate 2a include a glass substrate, a plastic substrate and a metal substrate. Examples of the glass substrate include a soda-lime glass substrate and a non-alkali glass substrate. Examples of the plastic substrate include a polyethylene terephthalate (PET) substrate and a polyethylene naphthalate (PEN) substrate. Examples of the metal substrate include a substrate made of metal such as aluminum and stainless.

The organic EL element 4a is disposed on the first substrate 2a. The phrase “disposed on the first substrate 2a” includes not only structure where the organic EL element 4a is directly disposed on the first substrate 2a, but also structure where appropriate layer(s) such as a light extraction layer be positioned between the organic EL element 4a and the first substrate 2a. The light extraction layer is defined as a layer to, when light emitted from the organic EL element 4a is extracted outside the organic EL light-emitting device 1a, increase amount of extracted light. Examples of the light extraction layer include a layer made of resin or glass having a refractive index greater than a refractive index of the first substrate 2a, and a layer made of resin containing light scattering particles.

The organic EL element 4a includes a first electrode 15a placed on the first substrate 2a, a second electrode 16a disposed to face the first electrode 15a, and an organic layer positioned between the first electrode 15a and the second electrode 16a. The first electrode 15a serves as an anode and the second electrode 16a serves as a cathode. However, the first electrode 15a may serve as a cathode and the second electrode 16a may serve as an anode.

It is preferable that the first electrode 15a have a light transmissive property. In this case, light emitted from the organic layer can emerge outside through the first electrode 15a. Examples of materials of the first electrode 15a include an electrode material that has a large work function, such as metal, alloy, or electrically conductive compound, and a mixture thereof. Examples of these materials of the first electrode 15a include ITO (Indium Tin Oxide), IZO (Indium Zinc Oxide), AZO (Al-dope ZnO), GZO (Ga-dope ZnO), silver, magnesium, aluminum, graphene, carbon nanotube, and laminated film including two or more of these materials.

It is preferable that the second electrode 16a have light reflectivity. In this case, light emitted from the organic layer toward the second electrode 16a can be reflected by the second electrode 16a and emerge outside through the first electrode 15a. Examples of materials of the second electrode 16a include an electrode material that has a small work function, such as metal, alloy, or electrically conductive compound, and a mixture thereof. Examples of these materials of the second electrode 16a include silver, natrium, lithium, magnesium, aluminum, alloy including two or more of these materials, and laminated film including two or more metals of these materials.

Note that the first electrode 15a may have light reflectivity, and the second electrode 16a may have a light transmissive property. Alternatively, both the first electrode 15a and the second electrode 16a may have a light transmissive property.

The organic layer is placed between the first electrode 15a and the second electrode 16a. The organic layer includes an organic light-emitting layer 17a. In a case where the first electrode 15a serves as a hole injection electrode (anode) and the second electrode 16a serves as an electron injection layer (cathode), the organic layer includes a laminate structure including a hole transport layer, the organic light-emitting layer 17a and an electron transport layer in this order, for example. Note that either of the hole transport layer and the electron transport layer may be absent, or both thereof may be absent.

It is sufficient that the hole transport layer has high hole mobility, and appropriate material selected from conventionally known compounds may be used as material of the hole transport layer. Examples of materials of the hole transport layer include a porphyrin compound such as copper phthalocyanine, aromatic tertiary amine such as 4,4′-bis[N-(naphthyl)-N-phenyl-amino]biphenyl (NPB).

Examples of materials of the organic light-emitting layer 17a include an aromatic dimethylidyne compound such as 4,4′-bis(2,2′-diphenylvinyl)-biphenyl (DPVBi), a styrylbenzene compound such as 1,4-bis(2-methylstyryl)benzene, triazole derivative such as 3-(4-biphenyl)-4-phenyl-5-t-butylphenyl-1,2,4-triazole (TAZ).

It is sufficient that the electron transport layer has a function to transport electrons injected from the electron injection layer (cathode) to the organic light-emitting layer 17a. Materials of the electron transport layer may be selected from conventionally known compounds. Examples of materials of the electron transport layer include a metal complex compound such as tris(8-hydroxyquinolinate)aluminum, nitrogen-containing five-membered ring derivative such as 2,5-bis(1-phenyl)-1,3,4-oxazole.

The second substrate 3a is disposed so as to face the first substrate 2a with the organic EL element 4a in-between. The second substrate 3a is, for example, a transparent plate having a shape same as a shape of the first substrate 2a, and has uniform thickness and surface smoothness. Examples of materials of the second substrate 3a include glass material such as soda-lime glass and non-alkali glass, metal material such as aluminum and stainless, and resin material such as polyethylene terephthalate (PET) and polyethylene naphthalate (PEN). In a case where the second substrate 3a is made of resin material, a SiON film, a SiN film or the like may be formed on a surface of the first substrate 2a to suppress permeation of moisture.

The sealing member 5a is disposed between the first substrate 2a and the second substrate 3a so as to surround the organic EL element 4a. The sealing member 5a is to prevent intrusion of moisture outside the organic EL light-emitting device 1a (in outer air) into an inside of the organic EL light-emitting device 1a. It is preferable that material of the sealing member 5a has moisture permeability of equal to or less than 60 g/m^{2·} 24 hour which is obtained by moisture permeability test (cup method) of moisture-proof packaging material defined in JIS Z0208. Thereby, it is possible to effectively prevent intrusion of moisture in outer air into the inside of the organic EL light-emitting device 1a. Examples of materials of the sealing member 5a include resin material such as epoxy resin and acrylic resin, and wax material such as paraffin wax and microcrystalline wax. The sealing member 5a may contain inorganic filler such as alumina, or hygroscopic material such as calcium oxide, strontium oxide, barium oxide and silica. As the material of the sealing member 5a, frit material such as glass frit may be used. It is preferable that the sealing member 5a have a thickness equal to or less than 300 μm. When the thickness of the sealing member 5a is equal to or less than 300 μm, it is possible to effectively prevent intrusion of moisture into the inside of the organic EL light-emitting device 1a. Further, it is preferable that a width of the sealing member 5a be equal to or more than 0.1 mm. When the width of the sealing member 5a is equal to or more than 0.1 mm, it is possible to effectively prevent intrusion of moisture into the inside of the organic EL light-emitting device 1a. The sealing member 5a can be formed by use of publicly known methods such as a dispensing method, a printing method, and an ink-jet method.

In the present embodiment, the organic EL light-emitting device 1a includes the protection layer 40a, the hygroscopic member 10a and the moisture permeable member 20a within the space 11a enclosed by the first substrate 2a, the second substrate 3a and the sealing member 5a.

The protection layer 40a is to cover a whole outer surface of the organic EL element 4a and prevent the organic EL element 4a and the hygroscopic member 10a from being in contact with each other. Material of the protection layer 40a is not particularly limited if the material does not have harmful effects to deteriorate characteristics of the organic EL element 4a. Examples of materials of the protection layer 40a include epoxy resin. The protection layer 40a may have an appropriate thickness enough to prevent contact between the organic EL element 4a and the hygroscopic member 10a. The protection layer 40a can be formed by use of publicly known methods such as a spin coating method, a dip method and a method.

The hygroscopic member 10a is configured to absorb moisture within the space 11a. In the present embodiment, as shown in FIG. 1, the hygroscopic member 10a is made of a solid material 6a (hereinafter, referred to as a solid moisture hygroscopic material 6a) having a hygroscopic property. Note that the solid hygroscopic material 6a is defined as a solid material made of material which is likely to absorb moisture such as vapor. The solid hygroscopic material 6a is prepared by adding hygroscopic material to light curable resin such as epoxy resin, acrylic resin, and silicone resin, for example. The hygroscopic material may absorb moisture chemically or physically. Examples of the hygroscopic material include alkali metal and alkali earth metal such as calcium oxide, strontium oxide, barium oxide, sodium oxide, potassium oxide, sodium sulfate and calcium sulfate, and zeolite. It is preferable that a ratio of the hygroscopic material to the whole solid hygroscopic material 6a be equal to or more than 30 mass percent and less than 95 mass percent. If the ratio of the hygroscopic material is equal to or more 30 mass percent, the solid hygroscopic material 6a can effectively absorb moisture intruding into the space 11a. Further, if the ratio of the hygroscopic material is equal to or more than 95 mass percent, workability in forming the hygroscopic member 10a in the space 11a is decreased. A thickness of the hygroscopic member 10a is not particularly limited on the condition that the hygroscopic member 10a can absorb moisture intruding in the space 11a. The hygroscopic member 10a made of the solid hygroscopic material 6a can be formed by use of publicly known methods such as a dispense method, a printing method, and sputtering.

The moisture permeable member 20a is in contact with the hygroscopic member 10a and is configured to allow moisture within the space 11a to permeate. In the present embodiment, the moisture permeable member 20a is disposed directly on the hygroscopic member 10a and overlaps the whole hygroscopic member 10a in a plan view. In the present embodiment, as shown in FIG. 1, the moisture permeable member 20a is constituted by the empty space 8a formed in the space 11a. It is preferable that the empty space 8a be filled with gas. In this case, it is possible to keep the inside of the space 11a dry. Examples of gas filling the empty space 8a include inert gas with a dew point of about −70° C. such as nitrogen, helium, neon and argon.

The contact prevention member 30a is configured to prevent the organic EL element 4a and the second substrate 3a from being in contact with each other. Suppression of contact of the organic EL element 4a and the second substrate 3a includes suppression of contact of a layer covering the organic EL element 4a and the second substrate 3a as well as suppression of direct contact of the organic EL element 4a and the second substrate 3a. In other words, in the present embodiment, the contact prevention member 30a is configured to prevent contact between the hygroscopic member 10a covering the organic EL element 4a and the second substrate 3a.

In the present embodiment, it is preferable that the contact prevention member 30a be made of material same as material of the sealing member 5a. That is, it is preferable that the contact prevention member 30a be made of material having high moisture permeation resistance. Further, in a case where the second electrode 16a serves as an electrode having a light transmissive property and light emitted from the organic light-emitting layer 17a emerges outside by passing through the second electrode 16a, it is preferable that the contact prevention member 30a have a light transmissive property. In this case, light emitted from the organic EL element 4a can emerge outside without being attenuated. Examples of materials of the contact prevention member 30a include resin material such as epoxy resin and acrylic resin. Additionally, the contact prevention member 30a may contain inorganic filler such as alumina, or hygroscopic material such as calcium oxide, strontium oxide, barium oxide and silica. The contact prevention member 30a is formed into a shape capable of suppressing contact of the organic EL element 4a and the second substrate 3a. The shape of the contact prevention member 30a is not particularly limited if the shape does not have harmful effects to deteriorate characteristics of the organic EL element 4a. Examples of the shape of the contact prevention member 30a include a circular cylindrical shape and a cone shape. A position of the contact prevention member 30a is not particularly limited, but the contact prevention member 30a is preferably positioned on the organic EL element 4a. In this case, even when the second substrate 3a is bent by external force, it is possible to suppress the organic EL element 4a and the second substrate 3a from being in contact with each other. Further, the number of contact prevention members 30a is not particularly limited, but may be set to an appropriate number. The contact prevention member 30a can be formed by use of publicly known methods such as a dispense method, a printing method, and an ink-jet method.

In the present embodiment, the inorganic film 51a covering the organic EL element 4a is positioned between the organic EL element 4a and the protection layer 40a. Therefore, intrusion of moisture into the organic EL element 4a is further suppressed and sealing performance is improved.

It is preferable that the inorganic film 51a be made of material which has high moisture permeation resistance and is stable to moisture such as vapor. Material of the inorganic film 51a may include one or more kinds of materials selected from: silicon compounds such as silicon nitride, silicon oxide, silicon oxynitride and silicon carbide; aluminum compounds such as aluminum oxide, aluminum nitride, and aluminum silicate; zirconium oxide; tantalum oxide; titanium oxide: and titanium nitride. It is sufficient that the inorganic film 51a has enough thickness to cover a whole outer surface of the organic EL element 4a. The inorganic film 51a can be formed by a plasma chemical vapor deposition method, sputtering, ion plating or the like, for example.

Alternatively, the organic EL light-emitting device 1a may be devoid of the inorganic film 51a, and the protection layer 40a may directly cover the organic EL element 4a.

In order to manufacture the organic EL light-emitting device 1a according to the present embodiment, first, the organic EL element 4a is formed, for example, by forming the first electrode 15a (anode), the hole transport layer, the organic light-emitting layer 17a, the electron transport layer and the second electrode 16a (cathode) on the first substrate 2a. Thereafter, the first substrate 2a provided with the organic EL element 4a is placed under an inert gas atmosphere such as an inside of a glove box with circulation of nitrogen with a dew point of −70° C., and the following steps are performed within the glove box.

First, the organic EL element 4a placed on the first substrate 2a is disposed so as to face the second substrate 3a.

Next, the inorganic film 51a is formed so as to cover the whole outer surface of the organic EL element 4a by a plasma chemical vapor deposition, for example. In a case where the organic EL light-emitting device 1a does not include the inorganic film 51a, the protection layer 40a is formed so as to cover the whole outer surface of the organic EL element 4a. Thereafter, the hygroscopic member 10a is formed by coating the whole outer surface of the protection layer 40a with the solid hygroscopic material 6a. Further, the appropriate number of the contact prevention members 30a are formed on the hygroscopic member 10a. Thereafter, the sealing member 5a is disposed at a periphery of the first substrate 2a in such a way that the sealing member 5a is not in contact with the organic EL element 4a. In this configuration, the first substrate 2a and the second substrate 3a are moved close to each other until the contact prevention member 30a reaches the second substrate 3a. Further, the contact prevention member 30a is bonded to the second substrate 3a. Thereafter, the first substrate 2a and the second substrate 3a are bonded to each other via the sealing member 5a under a pressure of approximately 10000 Pa. Thereby, the organic EL light-emitting device 1a is obtained.

As described above, in the present embodiment, the organic EL light-emitting device 1a includes the hygroscopic member 10a made of the solid hygroscopic material 6a having a hygroscopic property within the space 11a enclosed by the first substrate 2a, the second substrate 3a and the sealing member 5a. Therefore, even when moisture intrudes into the space 11a, the hygroscopic member 10a can absorb such moisture. Thereby, it is possible to improve the effect of preventing intrusion of moisture into the organic EL element 4a.

In the present embodiment, the organic EL light-emitting device 1a includes the moisture permeable member 20a which is the empty space 8a formed in the space 11a. In this structure, even when moisture intrudes into the space 11a, the moisture permeable member 20a diffuses such moisture, and thereby it is possible to prevent intensive intrusion of moisture from one direction. Therefore, the whole hygroscopic member 10a can evenly absorb moisture. Accordingly, the hygroscopic member 10a effectively absorbs moisture and thereby it is possible to further improve the effect of preventing intrusion of moisture into the organic EL element 4a.

The contact prevention member 30a is made of material same as material of the sealing member 5a. In this case, the contact prevention member 30a made of material having high moisture permeation resistance is disposed in the space 11a, and therefore it is possible to further improve the effect of preventing intrusion of moisture into the organic EL element 4a.

Accordingly, in the organic EL light-emitting device 1a of the present embodiment, it is possible to improve the effect of preventing intrusion of moisture into the organic EL element 4a and maintain a stable light-emitting property for a long period.

Structure of the organic EL light-emitting device 1a is not limited to the first embodiment. For example, a position of the hygroscopic member 10a is not limited to the position as shown in the first embodiment. In the first embodiment, the hygroscopic member 10a is formed on the first substrate 2a so as to cover the organic EL element 4a and the protection layer 40a; however, the hygroscopic member 10a may be provided to the second substrate 3a.

In the first embodiment, the contact prevention member 30a having a conductive property may be in contact with the second electrode 16a in the organic EL element 4a. The organic EL light-emitting device having such structure is exemplified by an organic EL light-emitting device 1b according to the second embodiment is shown in FIG. 2.

The organic EL light-emitting device 1b according to the present embodiment includes a first substrate 2b, an organic EL element 4b, a second substrate 3b and a sealing member 5b. The organic EL element 4b is disposed on the first substrate 2b. The second substrate 3b is disposed so as to face the first substrate 2b with the organic EL element 4b in-between. The sealing member 5b is disposed between the first substrate 2b and the second substrate 3b so as to surround the organic EL element 4b. Further, the organic EL light-emitting device 1b includes a protection layer 40b, a hygroscopic member 10b, a moisture permeable member 20b and a contact prevention member 30b within a space 11b enclosed by the first substrate 2b, the second substrate 3b and the sealing member 5b. The organic EL element 4b includes a first electrode 15b placed on the first substrate 2b, a second electrode 16b disposed so as to face the first electrode 15b, and an organic light-emitting layer 17b positioned between the first electrode 15b and the second electrode 16b. The protection layer 40b covers the organic EL element 4b. The hygroscopic member 10b is configured to absorb moisture within the space 11b. The hygroscopic member 10b is made of a solid hygroscopic material 6b having a hygroscopic property. The moisture permeable member 20b is in contact with the hygroscopic member 10b and is configured to allow moisture within the space 11b to permeate. The moisture permeable member 20b is an empty space 8b formed in the space 11b. The contact prevention member 30b is configured to prevent contact between the organic EL element 4b and the second substrate 3b.

An inorganic film 51b covering the organic EL element 4b is positioned between the organic EL element 4b and the protection layer 40b. Alternatively, the organic EL light-emitting device 1b may be devoid of the inorganic film 51b, and the protection layer 40b may directly cover the organic EL element 4b.

The first substrate 2b, the organic EL element 4b, the second substrate 3b, the sealing member 5b, the hygroscopic member 10b, the moisture permeable member 20b, the protection layer 40b and the inorganic film 51b are same in structure as the first substrate 2a, the organic EL element 4a, the second substrate 3a, the sealing member 5a, the hygroscopic member 10a, the moisture permeable member 20a, the protection layer 40a and the inorganic film 51a of the first embodiment, respectively.

In the organic EL light-emitting device 1b according to the present embodiment, the contact prevention member 30b has a conductive property and is in contact with the second electrode 16b in the organic EL element 4b.

The contact prevention member 30b is configured to prevent contact between the organic EL element 4b and the second substrate 3b. As is the case with the first embodiment, preventing the contact between the organic EL element 4b and the second substrate 3b includes preventing contact between a layer covering the organic EL element 4b and the second substrate 3b as well as preventing direct contact between the organic EL element 4b and the second substrate 3b. In other words, in the present embodiment, the contact prevention member 30b is configured to prevent contact between the hygroscopic member 10b covering the organic EL element 4b and the second substrate 3b.

In the present embodiment, the contact prevention member 30b is made of electrically conductive material. Further, it is preferable that the contact prevention member 30b be light transmissive. In this case, light emitted from the organic EL element 4a can emerge outside without being attenuated. Examples of materials of the contact prevention member 30b include a conductive polymer.

It is also preferable that the contact prevention member 30b be made of conductive paste containing conductive particles (e.g., silver powder) and a binder. In this case, it is possible to ensure the electrically conductive property of the contact prevention member 30b and nevertheless to allow the contact prevention member 30b to effectively prevent contact of the organic EL element 4b and the second substrate 3b.

The contact prevention member 30b has a shape capable of preventing contact of the organic EL element 4b and the second substrate 3b. The shape of the contact prevention member 30b is not particularly limited except for shapes which may cause harmful effects to deteriorate characteristics of the organic EL element 4b. Examples of the shape of the contact prevention member 30b include a circular cylindrical shape and a cone shape.

In a case where the contact prevention member 30b is made of conductive paste, it is preferable that a width of the contact prevention member 30b in a plan view be equal to or less than 100 μm. In this case, the contact prevention member 30b is unlikely to be seen from outside. Additionally, the contact prevention member 30b is unlikely to attenuate light emitted from the organic EL element 4b.

A position of the contact prevention member 30b is not particularly limited, but it is preferable that the contact prevention member 30b be positioned on the organic EL element 4b. In this configuration, even when the second substrate 3b is bent by external force or the like, it is possible to prevent contact of the organic EL element 4b and the second substrate 3b. Further, the number of the contact prevention members 30b is not particularly limited, but may be set to an appropriate number. The contact prevention member 30b can be formed by use of publicly known methods such as a dispensing method, a printing method, and an ink-jet method.

In the present embodiment, the contact prevention member 30b penetrates through the hygroscopic member 10b, the protection layer 40b and the inorganic film 51b so as to be in direct contact with the second electrode 16b.

In the present embodiment, by contact between the contact prevention member 30b having a conductive property and the second electrode 16b, the contact prevention member 30b can serve as a power feeder. In this description, the power feeder has a conductive property and is configured to, by being in contact with an electrode and being interposed between the electrode and an external power source, facilitate power supply from the external power source to the electrode. Thereby, performance of power feeding to the organic EL element 4b is improved. Particularly, in a case where the second electrode 16b is a light-transmissive electrode, the second electrode 16b tends to not have high conductive property; however, even in such a case, the contact prevention member 30b serves as power feeder and thereby it is possible to ensure high performance of power feeding to the organic EL element 4b. The organic EL light-emitting device 1b of the present embodiment is particularly effective for a case where the second electrode 16b and the second substrate 3b have light transmissive properties and light emitted from the organic EL element 4b emerges outside through the second substrate 3b. In this case, light emitted from the organic EL element 4b can emerge outside through the second substrate 3b while high performance of power feeding to the organic EL element 4b can be ensured.

In the present embodiment, there is a conductive layer 18b disposed on a surface of the second substrate 3b facing the first substrate 2b, and the conductive layer 18b and the contact prevention member 30b are in contact with each other. In other words, the contact prevention member 30b is in contact with the second electrode 16b and the conductive layer 18b and thereby the contact prevention member 30b electrically interconnects the organic EL light-emitting device 1b and the conductive layer 18b.

Examples of materials of the conductive layer 18b include ITO (Indium Tin Oxide), IZO (Indium Zinc Oxide), AZO (Al-dope ZnO), GZO (Ga-dope ZnO), silver, magnesium, aluminum, graphene, carbon nanotube, and a laminated film including two or more layers of these materials.

In a case where the second electrode 16b and the second substrate 3b have light transmissive properties, it is preferable that the conductive layer 18b also have a light transmissive property. In this case, light emitted from the organic EL element 4b can emerge outside through the conductive layer 18b and the second substrate 3b. In a case where the conductive layer 18b has a light transmissive property, it is preferable that the conductive layer 18b be made of ITO (Indium Tin Oxide), IZO (Indium Zinc Oxide), AZO (Al-dope ZnO), GZO (Ga-dope ZnO), silver having a thickness equal to or less than 20 nm, magnesium having a thickness equal to or less than 20 nm, aluminum having a thickness equal to or less than 20 nm, a laminated film including two or more layers of these metals, or the like. The conductive layer 18b can be formed by an appropriate method such as sputtering, a deposition method, and coating.

The conductive layer 18b has a sheet shape, for example. The conductive layer 18b may have a grid shape.

In the present embodiment, the conductive layer 18b is electrically connected with the second electrode 16b of the organic EL element 4b and therefore the conductive layer 18b can be used for supplying power to the organic EL element 4b.

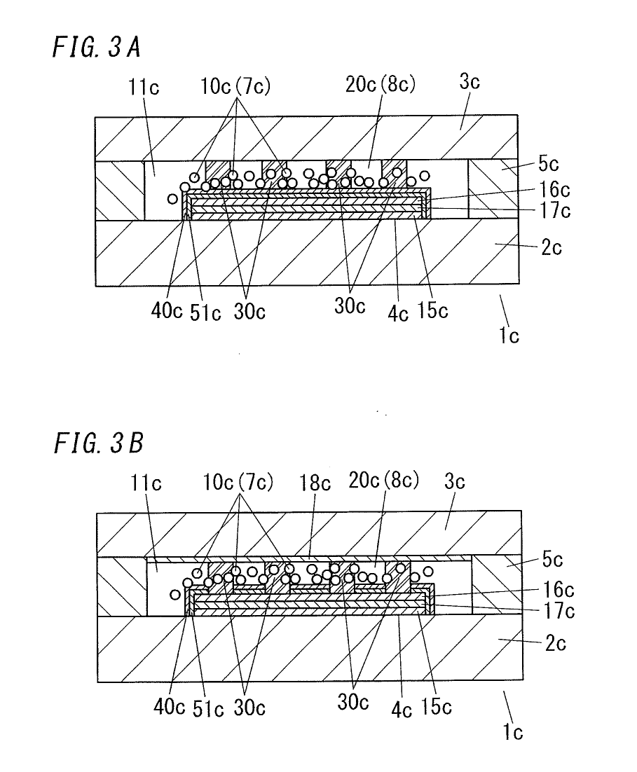

In the embodiment, the hygroscopic member 10a need not be made of solid hygroscopic material having a hygroscopic property. The organic EL light-emitting device of this case is exemplified by an organic EL light-emitting device 1c according to the third embodiment shown in FIG. 3A.

The organic EL light-emitting device 1c according to the present embodiment includes a first substrate 2c, an organic EL element 4c, a second substrate 3c and a sealing member 5c. The organic EL element 4c is disposed on the first substrate 2c. The second substrate 3c is disposed so as to face the first substrate 2c with the organic EL element 4c in-between. The sealing member 5c is disposed between the first substrate 2c and the second substrate 3c so as to surround the organic EL element 4c. Further, the organic EL light-emitting device 1c includes a protection layer 40c, a hygroscopic member 10c, a moisture permeable member 20c and a contact prevention member 30c within a space 11c enclosed by the first substrate 2c, the second substrate 3c and the sealing member 5c. The organic EL element 4c includes a first electrode 15c placed on the first substrate 2c, a second electrode 16c disposed so as to face the first electrode 15c, and an organic light-emitting layer 17c positioned between the first electrode 15c and the second electrode 16c. The protection layer 40c covers the organic EL element 4c. The hygroscopic member 10c is configured to absorb moisture within the space 11b. The moisture permeable member 20c is in contact with the hygroscopic member 10c and is configured to allow moisture within the space 11c to permeate. The moisture permeable member 20c is an empty space 8c formed in the space 11c. The contact prevention member 30c is configured to prevent contact between the organic EL element 4c and the second substrate 3c.

An inorganic film 51c covering the organic EL element 4c is positioned between the organic EL element 4c and the protection layer 40c. Alternatively, the organic EL light-emitting device 1c may be devoid of the inorganic film 51c, and the protection layer 40c may directly cover the organic EL element 4c.

The first substrate 2c, the organic EL element 4c, the second substrate 3c, the sealing member 5c, the moisture permeable member 20c, the contact prevention member 30c, the protection layer 40c and the inorganic film 51c are same in structure as the first substrate 2a, the organic EL element 4a, the second substrate 3a, the sealing member 5a, the moisture permeable member 20a, the contact prevention member 30a, the protection layer 40a and the inorganic film 51a of the first embodiment, respectively.

In the organic EL light-emitting device 1c according to the present embodiment, the hygroscopic member 10c is not made of solid hygroscopic material having a hygroscopic property. Except for this point, the organic EL light-emitting device 1c has the same structure as the organic EL light-emitting device 1c according to the first embodiment.

In the present embodiment, as shown in FIG. 3A, the hygroscopic member 10c is made of powdery material 7c (hereinafter, referred to as powdery hygroscopic material 7c) having a hygroscopic property. Note that the powdery hygroscopic material 7c is powder particle material made of material which is likely to absorb moisture such as vapor. Examples of the powdery hygroscopic material 7c include an alkali metal compound and an alkali earth metal compound such as calcium oxide, strontium oxide, barium oxide, sodium oxide, potassium oxide, sodium sulfate and calcium sulfate, and zeolite. It is preferable that the powdery hygroscopic material 7c be activated under an inert gas atmosphere or in a vacuum. Thereby, it is possible to dramatically improve speed of moisture absorption by the powdery hygroscopic material 7c. The hygroscopic member 10c made of the powdery hygroscopic material 7c is formed by a spraying method, for example. In other words, the hygroscopic member 10c can be formed by directly spraying the powdery hygroscopic material 7c on the protection layer 40c so as to cover a whole outer surface of the protection layer 40c. An amount of the powdery hygroscopic material 7c may be an appropriate amount enough to absorb moisture intruding into the space 11c.

As is the case with the first embodiment, the moisture permeable member 20c according to the present embodiment is the empty space 8c formed in the space 11c. The empty space 8c is defined as part to which the powdery hygroscopic material 7c is not sprayed, and gaps between particles of the powdery hygroscopic material 7c.

To manufacture the organic EL light-emitting device 1c according to the present embodiment, the hygroscopic member 10c is formed by spraying the powdery hygroscopic material 7c so as to the whole outer surface of the protection layer 40c. Except for this point, the organic EL light-emitting device 1c can be manufactured by use of a method and a condition same as those for manufacturing the organic EL light-emitting device 1c according to the first embodiment.

In the present embodiment, the organic EL light-emitting device 1c includes the hygroscopic member 10c made of the powdery hygroscopic material 7c having a hygroscopic property within the space 11c enclosed by the first substrate 2c, the second substrate 3c and the sealing member 5c. In this structure, even when moisture intrudes into the space 11c, the hygroscopic member 10c absorbs the moisture. Therefore, it is possible to improve an effect of preventing intrusion of moisture into the organic EL element 4c.

The organic EL light-emitting device 1c includes the moisture permeable member 20c which is the empty space 8c formed in the space 11c. In this structure, even when moisture intrudes into the space 11c, the moisture permeable member 20c diffuses such moisture and thereby it is possible to prevent intensive intrusion of moisture from one direction. Therefore, the whole hygroscopic member 10c can evenly absorb moisture. Accordingly, the hygroscopic member 10c effectively absorbs moisture and thereby it is possible to further improve the effect of preventing intrusion of moisture into the organic EL element 4c.

The contact prevention member 30c is made of material same as material of the sealing member 5c. In this case, the contact prevention member 30c made of material having high moisture permeation resistance is disposed in the space 11c, and therefore it is possible to further improve the effect of preventing intrusion of moisture into the organic EL element 4c.

Accordingly, in the organic EL light-emitting device 1c of the present embodiment, it is possible to improve the effect of preventing intrusion of moisture into the organic EL element 4c and maintain a stable light-emitting property for a long period.

In the present embodiment, as is the case with the second embodiment, as shown in FIG. 3B, the contact prevention member 30c having a conductive property may penetrate through the protection layer 40c and the inorganic film 51c so as to be in contact with the second electrode 16c in the organic EL element 4c. Additionally, as is the case with the second embodiment, a conductive layer 18c is disposed on a surface of the second substrate 3c facing the first substrate 2c, and the contact prevention member 30c may be in contact with the conductive layer 18c so as to electrically interconnect the second electrode 16c and the conductive layer 18c.

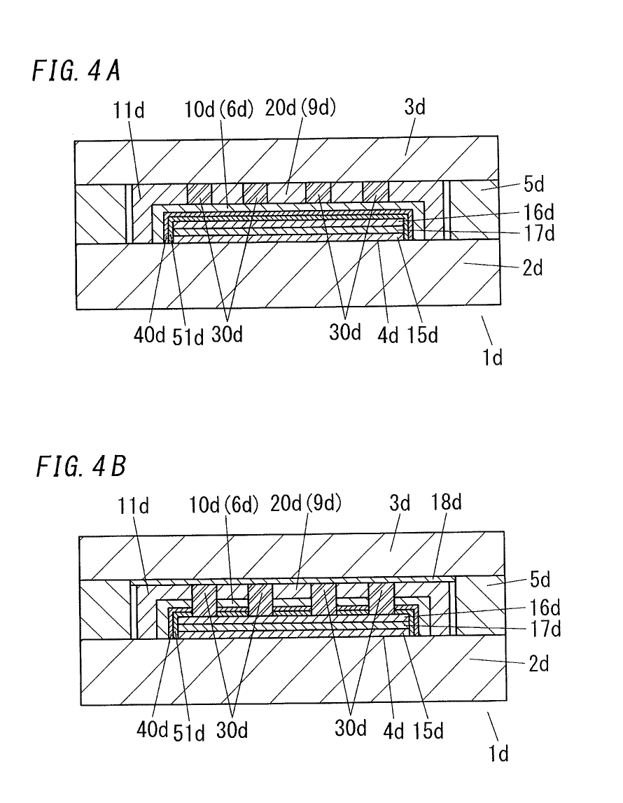

FIG. 4A shows an organic EL light-emitting device 1d according to the fourth embodiment.

The organic EL light-emitting device 1d according to the present embodiment includes a first substrate 2d, an organic EL element 4d, a second substrate 3d and a sealing member 5d. The organic EL element 4d is disposed on the first substrate 2d. The second substrate 3d is disposed so as to face the first substrate 2d with the organic EL element 4d in-between. The sealing member 5d is disposed between the first substrate 2d and the second substrate 3d so as to surround the organic EL element 4d. Further, the organic EL light-emitting device 1d includes a protection layer 40d, a hygroscopic member 10d, a moisture permeable member 20d and a contact prevention member 30d within a space 11d enclosed by the first substrate 2d, the second substrate 3d and the sealing member 5d. The organic EL element 4d includes a first electrode 15d placed on the first substrate 2d, a second electrode 16d disposed so as to face the first electrode 15d, and an organic light-emitting layer 17d positioned between the first electrode 15d and the second electrode 16d. The protection layer 40d covers the organic EL element 4d. The hygroscopic member 10d is configured to absorb moisture within the space 11d. The hygroscopic member 10d is made of a solid hygroscopic material 6d having a hygroscopic property. The moisture permeable member 20d is in contact with the hygroscopic member 10d and is configured to allow moisture within the space 11d to permeate. The contact prevention member 30d is configured to prevent contact between the organic EL element 4d and the second substrate 3d.

An inorganic film 51d covering the organic EL element 4d is positioned between the organic EL element 4d and the protection layer 40d. Alternatively, the organic EL light-emitting device 1d may be devoid of the inorganic film 51d, and the protection layer 40d may directly cover the organic EL element 4d.

The first substrate 2d, the organic EL element 4d, the second substrate 3b, the sealing member 5d, the hygroscopic member 10d, the contact prevention member 30d, the protection layer 40d and the inorganic film 51d are same in structure as the first substrate 2a, the organic EL element 4a, the second substrate 3a, the sealing member 5a, the hygroscopic member 10a, the contact prevention member 30a, the protection layer 40a and the inorganic film 51a of the first embodiment, respectively.

In the organic EL light-emitting device 1d according to the present embodiment, the moisture permeable member 20d is not an empty space formed in the space 11d. Except for this point, the organic EL light-emitting device 1d has the same structure as the organic EL light-emitting device 1a according to the first embodiment.

In the present embodiment, as shown in FIG. 4A, the moisture permeable member 20d is made of a material 9d (hereinafter, referred to as a moisture permeable material 9d) having moisture permeability. Note that the moisture permeable material 9d includes a material which is likely to allow moisture such as vapor to permeate. It is preferable that material of the moisture permeable material 9d have moisture permeability of equal to or less than 1000 g/m^{2·} 24 hour which is obtained by moisture permeability test (cup method) of moisture-proof packaging material defined in JIS Z0208. Examples of materials of the moisture permeable material 9d include urethane resin, polyester resin and polyamide resin. It is sufficient that the moisture permeable member 20d has an appropriate thickness enough to diffuse moisture intruding into the space 11d. The moisture permeable member 20d made of the moisture permeable material 9d can be formed by use of publicly known methods such as a spin coating method, a dip method and a spray method. The moisture permeable member 20d may be formed of a sheet-shaped product made of resin material having high moisture permeability such as urethane resin, polyester resin and polyamide resin.

To manufacture the organic EL light-emitting device 1d according to the present embodiment, the moisture permeable member 20d is formed, for example, by coating a whole outer surface of the hygroscopic member 10d with the moisture permeable material 9d. Except for this point, the organic EL light-emitting device 1d can be manufactured by use of a method and a condition same as those for manufacturing the organic EL light-emitting device 1a according to the first embodiment.

In the present embodiment, the hygroscopic member 10d made of the solid hygroscopic material 6d having a hygroscopic property is included within the space 11d enclosed by the first substrate 2d, the second substrate 3d and the sealing member 5d. In this structure, even when moisture intrudes into the space 11d, the hygroscopic member 10d absorbs the moisture. Therefore, it is possible to improve an effect of preventing intrusion of moisture into the organic EL element 4d.

The organic EL light-emitting device 1d includes the moisture permeable member 20d made of the moisture permeable material 9d having moisture permeability. In this structure, even when moisture intrudes into the space 11d, the moisture permeable member 20d diffuses the moisture, and thereby intensive intrusion of moisture from one direction is prevented. Therefore, the whole hygroscopic member 10d can evenly absorb moisture. Accordingly, the hygroscopic member 10d effectively absorbs moisture and thereby it is possible to further improve the effect of preventing intrusion of moisture into the organic EL element 4d.

In the present embodiment, the contact prevention member 30d made of material same as material of the sealing member 5d. In this case, the contact prevention member 30d made of material having high moisture permeation resistance is disposed in the space 11d, and therefore it is possible to further improve the effect of preventing intrusion of moisture into the organic EL element 4d.

Accordingly, in the organic EL light-emitting device 1d of the present embodiment, it is possible to improve the effect of preventing intrusion of moisture into the organic EL element 4d and maintain a stable light-emitting property for a long period.

In the present embodiment, as is the case with the second embodiment, as shown in FIG. 4B, the contact prevention member 30d having a conductive property may penetrate through the hygroscopic member 10d, the protection layer 40d and the inorganic film 51d so as to be in contact with the second electrode 16d in the organic EL element 4d. Additionally, as is the case with the second embodiment, a conductive layer 18d is disposed on a surface of the second substrate 3d facing the first substrate 2d, and the contact prevention member 30d may be in contact with the conductive layer 18d so as to electrically interconnect the second electrode 16d and the conductive layer 18d.

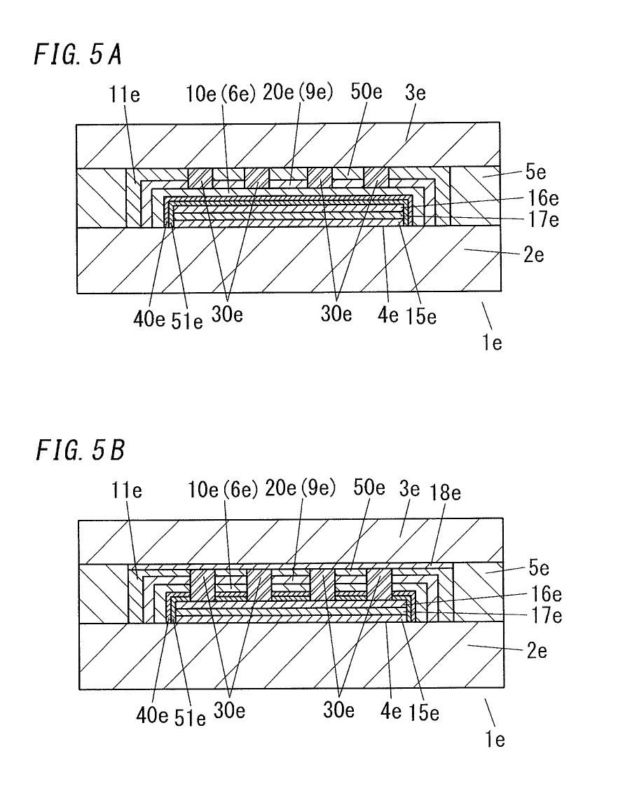

FIG. 5A shows an organic EL light-emitting device 1e in accordance with the fifth embodiment.

The organic EL light-emitting device 1e according to the present embodiment includes a first substrate 2e, an organic EL element 4e, a second substrate 3e and a sealing member 5e. The organic EL element 4e is disposed on the first substrate 2e. The second substrate 3e is disposed so as to face the first substrate 2e with the organic EL element 4e in-between. The sealing member 5e is disposed between the first substrate 2e and the second substrate 3e so as to surround the organic EL element 4e. Further, the organic EL light-emitting device 1e includes a protection layer 40e, a hygroscopic member 10e, a moisture permeable member 20e and a contact prevention member 30e within a space 11e enclosed by the first substrate 2e, the second substrate 3e and the sealing member 5e. The organic EL element 4e includes a first electrode 15e placed on the first substrate 2e, a second electrode 16e disposed so as to face the first electrode 15e, and an organic light-emitting layer 17e positioned between the first electrode 15e and the second electrode 16e. The protection layer 40e covers the organic EL element 4e. The hygroscopic member 10e is configured to absorb moisture within the space 11e. The hygroscopic member 10e is made of a solid hygroscopic material 6e having a hygroscopic property. The moisture permeable member 20e is in contact with the hygroscopic member 10e and is configured to allow moisture within the space 11e to permeate. The contact prevention member 30e is configured to prevent contact between the organic EL element 4e and the second substrate 3e.

An inorganic film 51e covering the organic EL element 4e is positioned between the organic EL element 4e and the protection layer 40e. Alternatively, the organic EL light-emitting device 1e may be devoid of the inorganic film 51e, and the protection layer 40e may directly cover the organic EL element 4e.

The first substrate 2e, the organic EL element 4e. the second substrate 3e, the sealing member 5e, the hygroscopic member 10e, the contact prevention member 30e, the protection layer 40e and the inorganic film 51c are same in structure as the first substrate 2a, the organic EL element 4a, the second substrate 3a, the sealing member 5a, the hygroscopic member 10a, the contact prevention member 30a, the protection layer 40a and the inorganic film 51a of the first embodiment, respectively.

In the organic EL light-emitting device 1e according to the present embodiment, the moisture permeable member 20e is not an empty space formed in the space 11e. In the present embodiment, as shown in FIG. 5A, the moisture permeable member 20e is made of a material 9e (hereinafter, referred to as a moisture permeable material 9e) having moisture permeability. Note that the moisture permeable material 9e includes a material which is likely to allow moisture such as vapor to permeate. It is preferable that material of the moisture permeable material 9e have moisture permeability of equal to or less than 1000 g/m^{2·} 24 hour which is obtained by moisture permeability test (cup method) of moisture-proof packaging material defined in JIS Z0208. Examples of materials of the moisture permeable material 9e include urethane resin, polyester resin and polyamide resin. The moisture permeable member 20e may have an appropriate thickness enough to diffuse moisture intruding into the space 11e. The moisture permeable member 20e made of the moisture permeable material 9e can be formed by use of publicly known methods such as a spin coating method, a dip method and a spray method. The moisture permeable member 20e may be formed of a sheet-shaped product made of resin material having high moisture permeability such as urethane resin, polyester resin and polyamide resin.

In the organic EL light-emitting device 1e according to the present embodiment, a whole outer surface of the hygroscopic member 10e is covered with the moisture permeable member 20e. Further, the organic EL light-emitting device 1e includes an inorganic film 50e (second inorganic film 50e) covering a whole outer surface of the moisture permeable member 20e. Except for this point, the organic EL light-emitting device 1e has the same structure as the organic EL light-emitting device 1d according to the fourth embodiment.

It is preferable that the second inorganic film 50e be made of material which has high moisture permeation resistance and is stable to moisture such as vapor. Material of the second inorganic film 50e may include one or more kinds of materials selected from: silicon compounds such as silicon nitride, silicon oxide, silicon oxynitride and silicon carbide; aluminum compounds such as aluminum oxide, aluminum nitride, and aluminum silicate; zirconium oxide; tantalum oxide; titanium oxide; and titanium nitride. It is sufficient that the second inorganic film 50e has thickness enough to cover a whole outer surface of the moisture permeable member 20e. The second inorganic film 50e can be formed by a plasma chemical vapor deposition method, sputtering, ion plating or the like, for example.

To manufacture the organic EL light-emitting device 1e according to the present embodiment, the second inorganic film 50e is formed so as to cover a whole outer surface of the moisture permeable member 20e by a plasma chemical vapor deposition method or the like. Except for this point, the organic EL light-emitting device 1e can be manufactured by use of a method and a condition same as those for manufacturing the organic EL light-emitting device 1d according to the fourth embodiment.

In the present embodiment, the organic EL light-emitting device 1e includes the hygroscopic member 10e made of the solid hygroscopic material 6e having a hygroscopic property within the space 11e enclosed by the first substrate 2e, the second substrate 3e and the sealing member 5e. Therefore, even when moisture intrudes into the space 11e, the hygroscopic member 10e absorbs such moisture. Thereby, it is possible to improve the effect of preventing intrusion of moisture into the organic EL element 4e.

The organic EL light-emitting device 1e includes the moisture permeable member 20e made of the moisture permeable material 9e. In this structure, even when moisture intrudes into the space 11e, the moisture permeable member 20e diffuses such moisture, and thereby it is possible to prevent intensive intrusion of moisture from one direction. Therefore, the whole hygroscopic member 10e can evenly absorb moisture. Accordingly, the hygroscopic member 10e effectively absorbs moisture and thereby it is possible to further improve the effect of preventing intrusion of moisture into the organic EL element 4e.

A whole outer surface of the hygroscopic member 10e is covered with the moisture permeable member 20e. Further, the organic EL light-emitting device 1e includes the second inorganic film 50e covering a whole outer surface of the moisture permeable member 20e. In this structure, the second inorganic film 50e is placed on the moisture permeable member 20e and therefore moisture is unlikely to intrude into the space 11e owing to presence of the second inorganic film 50e. Accordingly, it is possible to further improve the effect of preventing intrusion of moisture into the organic EL element 4e.

The contact prevention member 30e is made of material same as material of the sealing member 5e. In this case, the contact prevention member 30e made of material having high moisture permeation resistance is disposed in the space 11e, and therefore it is possible to further improve the effect of preventing intrusion of moisture into the organic EL element 4e.

Accordingly, in the organic EL light-emitting device 1e of the present embodiment, it is possible to improve the effect of preventing intrusion of moisture into the organic EL element 4e and maintain a stable light-emitting property for a long period.

In the present embodiment, as is the case with the second embodiment, as shown in FIG. 5B, the contact prevention member 30e having a conductive property may penetrate through the hygroscopic member 10e, the protection layer 40e and the inorganic film 51e so as to be in contact with the second electrode 16e in the organic EL element 4e. Additionally, as is the case with the second embodiment, a conductive layer 18e is disposed on a surface of the second substrate 3e facing the first substrate 2e, and the contact prevention member 30e may be in contact with the conductive layer 18e so as to electrically interconnect the second electrode 16e and the conductive layer 18e.

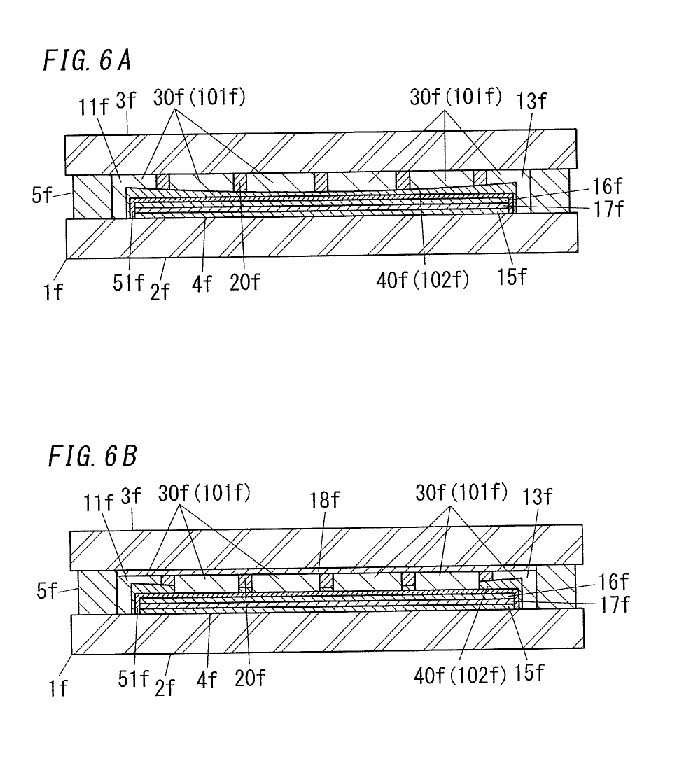

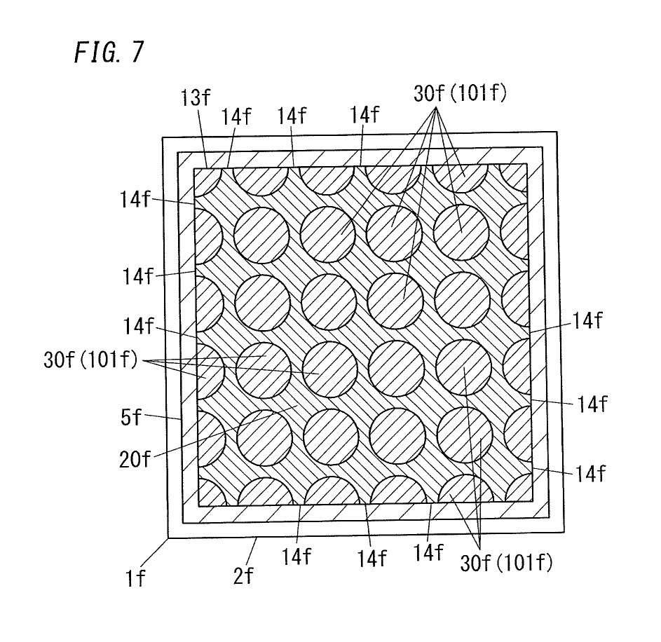

FIGS. 6A and 7 show an organic EL light-emitting device 1f according to the sixth embodiment.

The organic EL light-emitting device 1f according to the present embodiment includes a first substrate 2f, an organic EL element 4f, a second substrate 3f and a sealing member 5f. The organic EL element 4f is disposed on the first substrate 2f. The second substrate 3f is disposed so as to face the first substrate 2f with the organic EL element 4f in-between. The sealing member 5f is disposed between the first substrate 2f and the second substrate 3f so as to surround the organic EL element 4f. Further, the organic EL light-emitting device 1f includes a protection layer 40f, hygroscopic members 101f, 102f and 103f, a moisture permeable member 20f and a contact prevention member 30f within a space 11f enclosed by the first substrate 2f, the second substrate 3f and the sealing member 5f. The organic EL element 4f includes a first electrode 15f placed on the first substrate 2f, a second electrode 16f disposed so as to face the first electrode 15f, and an organic light-emitting layer 17f positioned between the first electrode 15f and the second electrode 16f. The protection layer 40f covers the organic EL element 4f. The hygroscopic members 101f, 102f and 103f are configured to absorb moisture within the space 11f. The moisture permeable member 20f is in contact with the hygroscopic members 101f, 102f and 103f and is configured to allow moisture within the space 11f to permeate. The contact prevention member 30f is configured to prevent contact between the organic EL element 4f and the second substrate 3f.

The following detailed explanations are made to the organic EL light-emitting device 1f according to the present embodiment.

The organic EL light-emitting device 1f includes the first substrate 2f, the second substrate 3f, the organic EL element 4f and the sealing member 5f. The second substrate 3f is disposed so as to face the first substrate 2f. The organic EL element 4f is placed on the first substrate 2f between the first substrate 2f and the second substrate 3f. The sealing member 5f is positioned between the first substrate 2f and the second substrate 3f. The sealing member 5f surrounds the organic EL element 4f. In brief, the organic EL element 4f is disposed in the space 11f enclosed by the first substrate 2f, the second substrate 3f and the sealing member 5f.

The organic EL light-emitting device 1f further includes a filling layer 13f. The filling layer 13f is disposed in the space 11f enclosed by the first substrate 2f, the second substrate 3f and the sealing member 5f. In the present embodiment, the filling layer 13f covers the organic EL element 4f. The phrase “the filling layer 13f covers the organic EL element 4f” means not only that the filling layer 13f is directly in contact with the organic EL element 4f, but also that another layer (e.g., a protection layer 40f described below) is positioned between the organic EL element 4f and the filling layer 13f. In the present embodiment, the organic EL light-emitting device 1f includes the protection layer 40f. The filling layer 13f includes the contact prevention member 30f and the moisture permeable member 20f having moisture permeability. The moisture permeable member 20f has an exposed surface 14f facing the sealing member 5f. The moisture permeable member 20f is formed inside the filling layer 13f to have the exposed surface 14f.

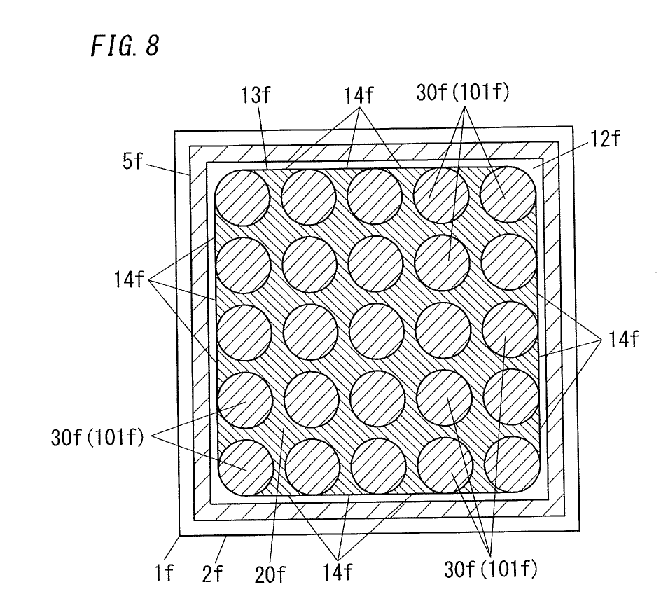

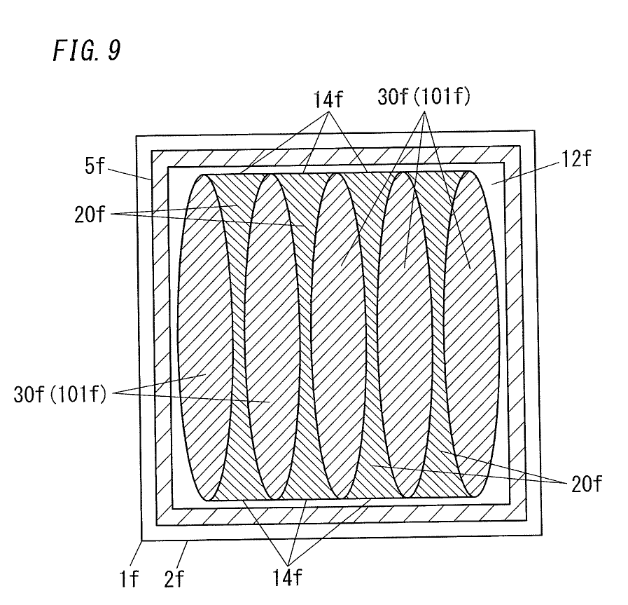

Note that the phrase “the exposed surface faces the sealing member” means not only that, as the present embodiment, the exposed surface 14f is in contact with the sealing member 5f, but also that the exposed surface 14f faces the sealing member 5f with a void 12f in-between as shown in FIG. 8 described below, and that the exposed surface 14f faces the sealing member 5f with the void 12f in-between as shown in FIG. 9 described below.

The organic EL light-emitting device 1f according to the present embodiment has the above structure, and therefore, even when moisture intrudes into the organic EL light-emitting device 1f through a vicinity of the sealing member 5f, such moisture is likely to move to an inside of the filling layer 13f through the exposed surface 14f. Accordingly, moisture is likely to be diffused within the filling layer 13f and unlikely to locally stay in the organic EL light-emitting device 1f. As a result, the organic EL element 4f becomes unlikely to be deteriorated by moisture.

The organic EL light-emitting device 1f includes the moisture permeable member configured to absorb moisture within the space 11f enclosed by the first substrate 2f, the second substrate 3f and the sealing member 5f. It is preferable that the moisture permeable member include at least one of the hygroscopic member 101f doubling as the contact prevention member 30f, the hygroscopic member 102f doubling as the protection layer 40f, and the hygroscopic member 103f dispersed in the moisture permeable member 20f. The hygroscopic member 101f doubling as the contact prevention member 30f may be defined as the contact prevention member 30f doubling as the hygroscopic member 101f. Further, the hygroscopic member 102f doubling as the protection layer 40f may be defined as the protection layer 40f doubling as the hygroscopic member 102f. Note that the organic EL light-emitting device 1f may include a moisture permeable member other than the three hygroscopic members 101f, 102f and 103f.

The following more detailed explanations are made to the structure of the present embodiment. The organic EL light-emitting device 1f includes the first substrate 2f, the second substrate 3f, the organic EL element 4f, the sealing member 5f and the filling layer 13f and further includes the protection layer 40f.

It is preferable that the first substrate 2f have a light transmissive property. The first substrate 2f may be colorless or colored. The first substrate 2f may be transparent or translucent. Material of the first substrate 2f is not limited. Examples of materials of the first substrate 2f include glass such as soda-lime glass and non-alkali glass, and plastic such as polyester, polyolefin, polyamide resin, epoxy resin, and fluorinated resin.

The organic EL element 4f is placed on the first substrate 2f. In this structure, the organic EL element 4f may be in direct contact with the first substrate 2f or another layer may be positioned between the organic EL element 4f and the first substrate 2f.

The organic EL element 4f includes, for example, the first electrode 15f disposed on the first substrate 2f, the second electrode 16f disposed so as to face the first electrode 15f, and the organic light-emitting layer 17f positioned between the first electrode 15f and the second electrode 16f. The first electrode 15f serves as an anode, and the second electrode 16f serves as a cathode. Note that the first electrode 15f and the second electrode 16f serve as a cathode and an anode, respectively.

It is preferable that the first electrode 15f have a light transmissive property. In this case, light emitted from the organic light-emitting layer 17f emerges outside through the first electrode 15f. Examples of materials of the first electrode 15f include an electrode material that has a large work function, such as metal, alloy, and electrically conductive compound, and a mixture thereof. Examples of these materials include ITO (Idium Tin Oxide), IZO (Indium Zinc Oxide), AZO (Al-dope ZnO), GZO (Ga-dope ZnO), silver, magnesium, aluminum, graphene, carbon nanotube, and a laminated film including two or more layers of these materials.

It is preferable that the second electrode 16f have a light transmissive property. In this case, light emitted from the organic light-emitting layer 17f toward the second electrode 16f is reflected by the second electrode 16f and emerges outside through the first electrode 15f. Examples of materials of the second electrode 16f include an electrode material that has a small work function, such as metal, alloy, and electrically conductive compound, and a mixture thereof. Examples of these materials include natrium, lithium, magnesium, and aluminum.

The first electrode 15f may have light reflectivity and the second electrode 16f may have a light transmissive property. Alternatively, both of the first electrode 15f and the second electrode 16f may have a light transmissive property.

The organic light-emitting layer 17f can be made of material publicly known as material for organic EL elements. Materials of the organic light-emitting layer 17f are not limited, but specific examples thereof include anthracene, naphthalene, pyrene, tetracene, coronene, perylene, phthaloperylene, naphthaloperylene, diphenylbutadiene, tetraphenylbutadiene, coumalin, oxadiazole, bisbenzoxazoline, bisstyryl, cyclopentadiene, quinoline-metal complex, tris(8-hydroxyquinolinate)aluminum complex, tris(4-methyl-8-quinolinate)aluminum complex, tris(5-phenyl-8-quinolinate)aluminum complex, aminoquinoline-metal complex, benzoquinoline-metal complex, tri-(p-terphenyl-4-yl)amine, 1-aryl-2,5-di(2-thienyl)pyrrole derivative, pyrane, quinacridone, rubrene, distyrylbenzene derivative, distyrylarylene derivative, distyrylamine derivative, various fluorescent dyes. Two or more kinds of the above materials may be mixed. Not only materials capable of fluorescent emission, but also materials capable of spin multiplet emission such as phosphorescent emission, and compounds including part capable of spin multiplet emission may be used. The organic light-emitting layer 17f may be formed by a dry process such as a vapor deposition method and a transfer method, or by a wet process such as a coating method.

One or more layers selected from a hole injection layer, a hole transport layer, an electron transport layer and an electron injection layer may be positioned between the first electrode 15f and the second electrode 16f. These layers can be made of appropriate material used for publicly known organic EL elements by a publicly known method.

The second substrate 3f is disposed so as to face the first substrate 2f with the organic EL element 4f in-between. The second substrate 3f is constituted by a member formed into a shape same as a shape of the first substrate 2f. Examples of materials of the second substrate 3f include glass material such as soda-lime glass and non-alkali glass, metal material such as aluminum and stainless, and resin material such as polyethylene terephthalate (PET) and polyethylene naphthalate (PEN). In a case where the second substrate 3f is made of resin material, a SiON film, a SiN film or the like may be formed on a surface of the second substrate 3f so as to prevent permeation of moisture.

The sealing member 5f is disposed between the first substrate 2f and the second substrate 3f so as to surround the organic EL element 4f. The sealing member 5f prevents intrusion of moisture into the organic EL light-emitting device 1f. It is preferable that material of the sealing member 5f have moisture permeability equal to or less than 60 g/m^{2·} 24 hour. The moisture permeability is obtained by moisture permeability test (cup method) of moisture-proof packaging material defined in JIS Z0208. Examples of materials of the sealing member 5f include resin material such as epoxy resin and acrylic resin, and wax material such as paraffin wax and microcrystalline wax. The sealing member 5f may contain inorganic filler such as alumina, or hygroscopic material such as calcium oxide, strontium oxide, barium oxide and silica, as an additive agent. As the material of the sealing member 5f, frit material such as glass frit may be used. The sealing member 5f can be formed by appropriate methods such as a dispensing method, a printing method, and an ink-jet method.

As shown in FIG. 7, the protection layer 40f covers the organic EL element 4f. That is, the protection layer 40f is positioned between the organic EL element 4f and the filling layer 13f. Therefore, intrusion of moisture into the organic EL element 4f is further prevented by the protection layer 40f. It is preferable that material of the protection layer 40f be unlikely to negatively affect the organic EL element 4f. It is preferable that the protection layer 40f be made of resin material such as epoxy resin and acrylic resin, for example.

It is also preferable that the protection layer 40f contain hygroscopic material. In this case, the protection layer 40f can double as the hygroscopic member 102f. In brief, the organic EL light-emitting device 1f can include the hygroscopic member 102f doubling as the protection layer 40f. In this case, the protection layer 40f absorbs moisture diffused within the moisture permeable member 20f of the filling layer 13f and thereby intrusion of moisture into the organic EL element 4f can be further prevented. Hygroscopic material is selected from materials for chemically absorbing moisture and materials for physically absorbing moisture, for example. More specifically, hygroscopic material may contain one or more of materials selected from alkali metal and alkali earth metal such as calcium oxide, strontium oxide, barium oxide, sodium oxide, potassium oxide, sodium sulfate and calcium sulfate, and zeolite. It is preferable that a ratio of the hygroscopic material to the protection layer 40f be 10 to 30 mass percent.

It is preferable that the protection layer 40f become thicker toward a periphery than at a center of the organic EL element 4f in a plan view of the organic EL element 4f. Note that the plan view is defined as a view of the organic EL light-emitting device 1f in a direction in which the first substrate 2f, the organic EL element 4f and the second substrate 3f are stacked. In this configuration, moisture is effectively absorbed by the protection layer 40f at a periphery of the organic EL element 4f. Therefore, moisture is effectively absorbed in a vicinity of the sealing member 5f which may cause intrusion of moisture, and accordingly intrusion of moisture into the organic EL element 4f is further prevented. The protection layer 40f can be formed by publicly known methods such as a spin coating method, a dip method and a spray method.

In the present embodiment, an inorganic film 51f covering the organic EL element 4f is positioned between the organic EL element 4f and the protection layer 40f. Thereby, intrusion of moisture into the organic EL element 4f is further prevented and sealing performance is improved.

It is preferable that the inorganic film 51f be made of material which has high moisture permeation resistance and is stable to moisture such as vapor. Material of the inorganic film 51f may include one or more kinds of materials selected from: silicon compounds such as silicon nitride, silicon oxide, silicon oxynitride and silicon carbide; aluminum compounds such as aluminum oxide, aluminum nitride, and aluminum silicate; zirconium oxide; tantalum oxide; titanium oxide; and titanium nitride. It is sufficient that the inorganic film 51f has thickness enough to cover a whole outer surface of the organic EL element 4f. The inorganic film 51f can be formed by a plasma chemical vapor deposition method, sputtering, or ion plating, for example.

Alternatively, the organic EL light-emitting device 1f may be devoid of the inorganic film 51f, and the protection layer 40f may directly cover the organic EL element 4f.

In the present embodiment, the filling layer 13f occupies portion within the space 11f enclosed by the first substrate 2f, the second substrate 3f and the sealing member 5f which is not occupied by the organic EL element 4f, the inorganic film 51f or the protection layer 40f.

The contact prevention member 30f in the filling layer 13f is configured to prevent contact between the organic EL element 4f and the second substrate 3f by being positioned between the organic EL element 4f and the second substrate 3f. The contact prevention member 30f can be made of appropriate molding material. The molding material contains resin material such as epoxy resin, acrylic resin and silicone resin, for example.

It is preferable that the molding material contain hygroscopic material. In other words, it is preferable that the contact prevention member 30f contain hygroscopic material. In this case, the contact prevention member 30f can double as the hygroscopic member 101f. In brief, the organic EL light-emitting device 1f can include the hygroscopic member 101f doubling as the contact prevention member 30f. In this case, moisture diffused within the moisture permeable member 20f is absorbed by the contact prevention member 30f and thereby intrusion of moisture into the organic EL element 4f is further prevented. Hygroscopic material can be selected from materials for chemically absorbing moisture and materials for physically absorbing moisture, for example. More specifically, hygroscopic material may contain one or more of materials selected from alkali metal and alkali earth metal such as calcium oxide, strontium oxide, barium oxide, sodium oxide, potassium oxide, sodium sulfate and calcium sulfate, and zeolite. It is preferable that a ratio of the hygroscopic material to the contact prevention member 30f be 10 to 30 mass percent.

The moisture permeable member 20f in the filling layer 13f is a void (empty space) formed in the filling layer 13f. In this structure, the void can effectively allow moisture to permeate and therefore moisture is likely to be diffused within the filling layer 13f.

The moisture permeable member 20f may be made of material (hereinafter, referred to as moisture permeable material) having moisture permeability. In this case as well, the moisture permeable member 20f can effectively allow moisture to permeate and therefore moisture is more likely to be diffused within the filling layer 13f. Note that the moisture permeable material includes a material which is likely to allow moisture to permeate. Specifically, it is preferable that the moisture permeable material have moisture permeability equal to or less than 1000 g/m^{2·} 24 hour. Note that the moisture permeability is obtained by moisture permeability test (cup method) of moisture-proof packaging material defined in JIS Z0208. Examples of materials of the moisture permeable material is made of molding material containing high moisture permeable resin such as urethane resin, polyester resin and polyamide resin.

The moisture permeable member 20f made of moisture permeable material may contain hygroscopic material. In other words, molding material for forming moisture permeable material may contain hygroscopic material. In this case, moisture diffused within the moisture permeable member 20f in the filling layer 13f is absorbed by the hygroscopic material contained in the moisture permeable material and thereby intrusion of moisture into the organic EL element 4f is further prevented. Hygroscopic material can be selected from materials for chemically absorbing moisture and materials for physically absorbing moisture, for example. More specifically, hygroscopic material may contain one or more of materials selected from alkali metal and alkali earth metal such as calcium oxide, strontium oxide, barium oxide, sodium oxide, potassium oxide, sodium sulfate and calcium sulfate, and zeolite. It is preferable that a ratio of the hygroscopic material to the moisture permeable member 20f be 10 to 30 mass percent.

As mentioned above, the moisture permeable member 20f is formed inside the filling layer 6e to have an exposed surface 14f facing the sealing member 5f. Further, it is preferable that the moisture permeable member 20f have a plurality of the exposed surface. In other words, it is preferable that the moisture permeable member 20f be formed so as to consecutively extend from one exposed surface 14f to another exposed surface 14f by passing through an inside of the filling layer 13f. In this structure, moisture is more likely to be diffused within the filling layer 13f. Accordingly, deterioration of the organic EL element 4f is further reduced.

It is also preferable that the filling layer 13f have a sea-island structure in which the moisture permeable member 20f and the contact prevention member 30f are arranged so that the moisture permeable member 20f and the contact prevention member 30f resemble sea and an island respectively in a plan view of the filling layer 13f. In this structure, moisture is more likely to be diffused within the moisture permeable member 20f, and accordingly deterioration of the organic EL element 4f is further reduced.

A ratio of the contact prevention member 30f and the moisture permeable member 20f in the filling layer 13f is not limited, but it is preferable that a volume ratio of the former to the latter be in a range of 10:1 to 2:1.

In the present embodiment, as shown in FIG. 7, the plurality of contact prevention members 30f each having a circular shape in a plan view are arranged in a matrix form at some interval. The moisture permeable member 20f is formed in a region between the contact prevention members 30f in which the contact prevention members 30f are not formed. Therefore, the moisture permeable member 20f is formed into a grid shape. Accordingly, the filling layer 13f has a sea-island structure in which the moisture permeable member 20f and the contact prevention member 30f are arranged so that the moisture permeable member 20f and the contact prevention member 30f resemble sea and an island respectively. The filling layer 13f is in contact with the sealing member 5f. Accordingly, one moisture permeable member 20f has the plurality of exposed surfaces 14f and the plurality of exposed surfaces 14f are in contact with the sealing member 5f.

FIGS. 8 to 10 show modified examples of the filling layer 13f according to the present embodiment. In the modified example shown in FIG. 8, the plurality of contact prevention members 30f each having a circular shape in a plan view are arranged in a matrix form at some interval, and the moisture permeable member 20f is formed in a region in which the contact prevention members 30f are not formed. In the modified example as well, one moisture permeable member 20f has the plurality of exposed surfaces 14f and the filling layer 13f has a sea-island structure. Thereby, deterioration of the organic EL element 4f is further reduced. In the modified example, the void 12f is formed between the filling layer 13f and the sealing member 5f. Therefore, the exposed surfaces 14f face the sealing member 5f with the void 12f in-between.

In the modified example shown in FIG. 9, the plurality of contact prevention members 30f each having an oval shape in a plan view are arranged in a direction of the minor axis of the oval shape at some interval, and the moisture permeable members 20f are formed in a region in which the contact prevention members 30f are not formed. In the modified example, each of the plurality of moisture permeable members 20f has a plurality of (two) exposed surfaces 14f. Therefore, deterioration of the organic EL element 4f is further reduced. In the modified example as well, the void 12e is formed between the filling layer 13f and the sealing member 5f. Accordingly, the exposed surfaces 14f face the sealing member 5f with the void 12f in-between.

In the modified example shown in FIG. 8, the filling layer 13f includes one moisture permeable member 20f having the plurality of exposed surfaces 14f, and in the modified example shown in FIG. 9, the filling layer 8f includes the plurality of moisture permeable members 20f each having the two exposed surfaces 14f; however, the filling layer 13f may include one or more moisture permeable members 20f each having one exposed surface 14f. For example, in the modified example shown in FIG. 9, the moisture permeable members 20f in the filling layer 13f each may be divided in the middle thereof, and thereby the filling layer 8f may include the plurality of moisture permeable members 20f each having one exposed surface 14f.

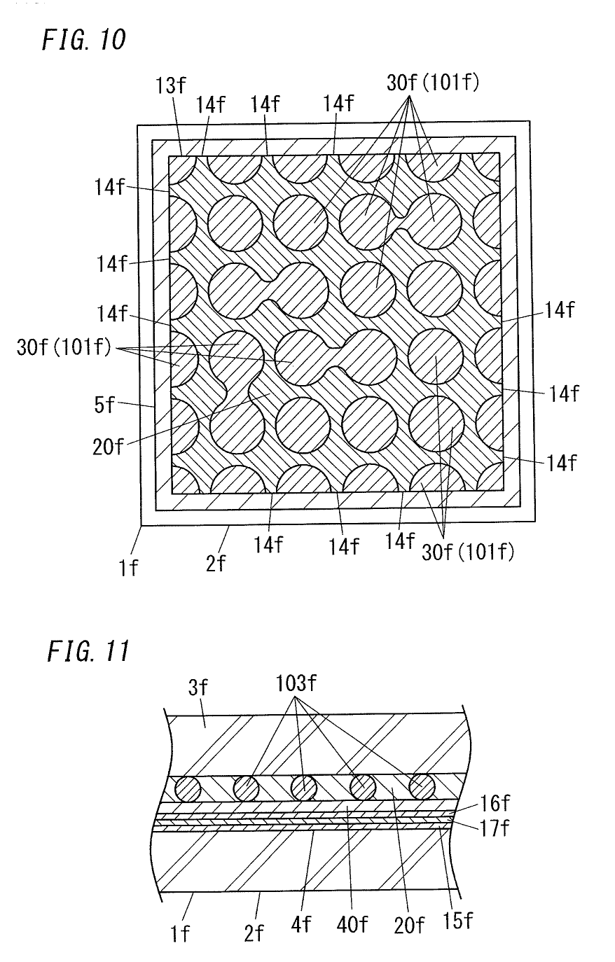

In the modified example shown in FIG. 10, the plurality of contact prevention members 30f each having a circular shape in a plan view are arranged in a matrix form. The contact prevention members 30f are arranged at some interval; however, some contact prevention members 30f adjacent to each other are not spaced and thus these contact prevention members 30f are formed integrally. In the modified example as well, the moisture permeable member 20f has the plurality of exposed surfaces 14f and the filling layer 13f has a sea-island structure. Thereby, deterioration of the organic EL element 4f is further reduced.

In the present embodiment and the modified example shown in FIG. 10, there is no void between the filling layer 13f and the sealing member 5f, and in the modified examples shown in FIGS. 8 and 9, the void 12f is formed along a whole boundary between the filling layer 13f and the sealing member 5f; however, a void may be partially formed between the filling layer 13f and the sealing member 5e.

The hygroscopic members 103f may, as shown in FIG. 11, be arranged dispersedly within the moisture permeable member 20f. In this structure, moisture is absorbed by the hygroscopic members 103f within the moisture permeable member 20f, and thereby deterioration of the organic EL element 4f is further reduced. The hygroscopic members 103f each can also serve as a spacer for keeping an interval between the first substrate 2f and the second substrate 3f. Thereby, it is possible to prevent the organic EL light-emitting device 1f from being deformed. Particularly, even when the moisture permeable member 20f is a void, the moisture permeable member 20f is held by the hygroscopic members 103f, and thereby it is possible to prevent the organic EL light-emitting device 1f from being deformed.

As shown in FIG. 11, it is preferable that the hygroscopic member 103f be hygroscopic particles each having a particle radius equal to a thickness of the moisture permeable member 20f. In this case, owing to increase in a surface area of the hygroscopic member 103f, moisture absorption efficiency of the hygroscopic member 103f is improved and thereby deterioration of the organic EL element 4f is further reduced. It is preferable that material of the hygroscopic particles be one or more materials selected from alkali metal and alkali earth metal such as calcium oxide, strontium oxide, barium oxide, sodium oxide, potassium oxide, sodium sulfate and calcium sulfate, and zeolite.

The filling layer 13f can be formed by an appropriate method. For example, the contact prevention member 30f can be formed by publicly known methods such as a dispensing method, a printing method, and sputtering. In a case where the moisture permeable member 20f is made of moisture permeable material, the moisture permeable material can be formed by publicly known methods such as a dispensing method, a printing method, and sputtering.

The filling layer 13f can also be formed by the following method. First, the organic EL element 4f and the sealing member 5f are placed on the first substrate 2f, and additionally the protection layer 40f is formed as necessary. Subsequently, molding materials for forming the contact prevention members 30f are placed at multiple points surrounded by the sealing member 5f on the first substrate 2f. Thereafter, the second substrate 3f is moved close to the first substrate 2f from the above. Then, the molding materials for forming the contact prevention members 30f are pressed and spread between the first substrate 2f and the second substrate 3f, and molded so as to form the plurality of contact prevention members 30f. Further, a void between the contact prevention members 30f serves as the moisture permeable member 20f. Thereby, the filling layer 13f is formed.

The filling layer 13f may be formed by the following method. First, the organic EL element 4f and the sealing member 5f are placed on the first substrate 2f, and additionally the protection layer 40f is formed as necessary. Subsequently, molding materials for forming the contact prevention members 30f are placed at multiple points surrounded by the sealing member 5f on the first substrate 2f. Further, molding materials for forming moisture permeable materials are also placed at multiple points surrounded by the sealing member 5f on the first substrate 2f. Subsequently, the second substrate 3f is moved close to the first substrate 2f from the above. Then, the molding materials for forming the contact prevention members 30f are pressed and spread between the first substrate 2f and the second substrate 3f, and molded so as to form the contact prevention members 30f. The molding materials for forming the moisture permeable material are also pressed and spread, and molded so as to form the plurality of moisture permeable member 20f between the contact prevention members 30f. In the above-mentioned manner, the contact prevention members 30f and the moisture permeable member 20f are formed.

In the present embodiment, as is the case with the second embodiment, as shown in FIG. 6B, the contact prevention member 30f having a conductive property may penetrate through the protection layer 40f and the inorganic film 51f so as to be in contact with the second electrode 16f in the organic EL element 4f. Additionally, as is the case with the second embodiment, a conductive layer 18f is disposed on a surface of the second substrate 3f facing the first substrate 2f, and the contact prevention member 30f may be in contact with the conductive layer 18f so as to electrically interconnect the second electrode 16f and the conductive layer 18f. In this structure, as further shown in FIG. 10, it is preferable that the plurality of contact prevention members 30f be disposed at some interval, and some contact prevention members 30f adjacent to each other be formed integrally. In this case, owing to increase in contact areas between the second electrode 16f and the contact prevention members 30f, the performance of the contact prevention members 30f as a power feeder is improved and thereby performance of power feeding to the organic EL element 4f is prominently improved.

All of the organic EL light-emitting devices 1a to 1f respectively according to the first to sixth embodiments are suitable as a light source of an illumination device.

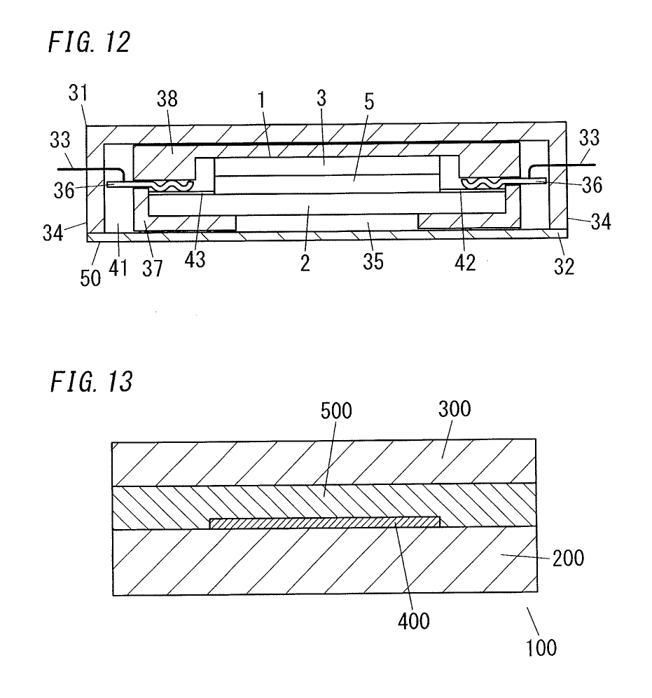

FIG. 12 shows an example of an illumination device 50 including an organic EL light-emitting device 1. The illumination device 50 includes the organic EL light-emitting device 1 and a device body 31 to hold the organic EL light-emitting device 1. The device body 31 includes a housing 34, a front panel 32 and wires 33 and feed terminals 36.

The organic EL light-emitting device 1 includes a first substrate 2, a second substrate 3 and a sealing member 5. In the organic EL light-emitting device 1, an organic EL element is disposed within a space enclosed by the first substrate 2, the second substrate 3 and the sealing member 5. The organic EL light-emitting device 1 has a structure same as the structure of the organic EL light-emitting device 1a according to the first embodiment. Note that the organic EL light-emitting device 1 may have the same structure as any one of the light-emitting devices 1b to 1f respectively according to the second to sixth embodiments.

There are a first wire 42 and a second wire 43 formed on the first substrate 2 of the organic EL light-emitting device 1. The first wire 42 and the second wire 43 are for power feeding and electrically connected to an organic EL element in the organic EL light-emitting device.

The housing 34 is configured to hold the organic EL light-emitting device 1. The housing 34 has a recess 41 and the organic EL light-emitting device 1 is held in the recess 41. The recess 41 has an opening covered with the front panel 32 having a light transmissive property.

There are a front case 37 and a rear case 38 disposed in the recess 41 of the housing 34. The organic EL light-emitting device 1 is held between the front case 37 and the rear case 38. The front case 37 is positioned between the first substrate and the front panel 32. The front case 37 has an opening 35 facing the first substrate 2 of the organic EL light-emitting device 1.

There are two wires 33 extending into the housing 34 from outside. These wires 33 are connected to an external power source. Further, there are two feed terminals 36 fixed between the front case 37 and the rear case 38. The two wires 33 are connected to the two feed terminals 36 respectively, and the two feed terminals 36 are connected to the first wire 42 and the second wire 43 respectively. Thereby, power is supplied to the organic EL light-emitting element in the organic EL light-emitting device 1 via the wires 33 and the feed terminals 36 from the external power source.

In the illumination device 50 having the above structure, when power is supplied to the organic EL light-emitting element in the organic EL light-emitting device 1 via the wires 33 and the feed terminals 36 from the external power source, the organic EL light-emitting element emits light and the light emerges outside through the first substrate 2, the opening 35 and the front panel 32.

### EXAMPLE

Specific examples of the present invention are described below. Note that the present invention is not limited to the following examples.

### Example 1

In the present example, an organic EL light-emitting device shown in FIG. 1 was made. Therefore, a hygroscopic member was made of solid hygroscopic member. Further, a moisture permeable member was formed, the moisture permeable member being an empty space formed in a space.

In the present Example, first, ITO glass (from Asahi Glass Co., Ltd.) was prepared as a first substrate. The ITO glass was made by forming an anode constituted by a transparent electrode having a sheet resistance of 7Ω/sq. on a glass substrate having a thickness of 0.4 mm. The first substrate was subjected to ultrasonic cleaning by use of a solution such as acetone, pure water and isopropyl alcohol for fifteen minutes, and then dried, and thereafter the first substrate was further cleaned by UV ozone cleaning. Next, the first substrate was put in a vacuum deposition equipment, and 4,4′-bis[N-(naphthyl)-N-phenyl-amino]biphenyl (α-NPD available from e-Ray Optoelectronics Technology Co., Ltd.) was deposited at a deposition rate of 1×10⁻¹⁰ to 2×10⁻¹⁰ m/s under reduced pressure of 1×10⁻⁻⁶ Torr (1.33×10⁻⁴ Pa) to form a film thereof having a thickness of 0.04 μm, and thereby a hole transport layer was formed on the anode. Next, tris(8-hydroxyquinolinate)aluminum complex (Alq3 available from e-Ray Optoelectronics Technology Co., Ltd.) was deposited at a deposition rate of 1×10⁻¹⁰ to 2×10⁻¹⁰ m/s so as to form a film thereof having a thickness of 0.04 μm, and thereby a layer doubling as an organic light-emitting layer and an electron transport layer was formed on the hole transport layer. Thereafter, LiF was deposited at a deposition rate of 0.5×10⁻¹⁰ to 1.0×10⁻¹⁰ m/s so as to form a film thereof having a thickness of 5×10⁻⁴ μm. Further, Al was deposited at a deposition rate of 10×10⁻¹⁰ m/s so as to form a film thereof having a thickness of 0.15 μm, and thereby a cathode was formed on the layer doubling as an organic light-emitting layer and an electron transport layer, and the organic EL element was provided to the first substrate.

The first substrate provided with the organic EL element was moved into a glove box with circulation of nitrogen with a dew point of −70° C. and the following steps were performed within the glove box. First, the organic EL element placed on the first substrate was disposed so as to face the second substrate. Next, UV curable epoxy resin seal material (available from Panasonic Corporation) was applied so as to cover a whole outer surface of the organic EL element, and cured by UV-irradiation, and thereby a protection layer having a thickness of 5 μm was formed. Thereafter, a solid hygroscopic material was applied so as to cover a whole outer surface of the protection layer, and cured by UV-irradiation, and thereby a hygroscopic member was formed. The solid hygroscopic material was prepared by adding calcium oxide (available from Kojundo Chemical Laboratory Co., Ltd.) to UV curable epoxy resin seal material (available from Panasonic Corporation) such that a percentage of calcium oxide was 30 mass percent. Further, epoxy resin (available from Nagase ChemteX Corporation) was put in a dot pattern so as to form contact prevention members each having a height equal to or less than 100 μm. Then, epoxy resin (available from Nagase ChemteX Corporation) was applied to a periphery of the first substrate by a dispensing method in such a way that epoxy resin was not in contact with the organic EL element and thereby a sealing member having a height of 100 μm was formed. In the state, the first substrate and the second substrate were moved closer to each other until the contact prevention members reached the second substrate. Further, the contact prevention members were bonded to the second substrate. Thereafter, the first substrate and the second substrate were bonded to each other by the seal material and thereby the organic EL light-emitting device having a structure shown in FIG. 1 was made.

After leaving the organic EL light-emitting device in a constant temperature and humidity chamber under a temperature of 50° C. and a humidity of 95% RH for one thousand hours, a light-emitting state of the organic EL light-emitting device was observed under a microscope. As a result, occurrence or growth of a dark spot having a diameter equal to or more than 50 μm was not found.

### Example 2

In the present example, an organic EL light-emitting device having a structure shown in FIG. 3 was made. That is, a hygroscopic member was made of powdery hygroscopic material. Further, a moisture permeable member was provided, the moisture permeable member being an empty space (part to which the powdery hygroscopic material was not sprayed, and gaps between particles of the powdery hygroscopic material) formed in a space.

The present example is different from the example 1 in that calcium oxide activated in a vacuum and having a particle size of 1 to 3 μm was sprayed as the powdery hygroscopic material so as to cover a whole outer surface of the protection layer, and thereby a hygroscopic member was formed.

Except for this point, the organic EL light-emitting device was obtained by use of a method and a condition same as those of the example 1.

As is the case with the example 1, after leaving the organic EL light-emitting device in a constant temperature and humidity chamber under a temperature of 50° C. and a humidity of 95% RH for one thousand hours, a light-emitting state of the organic EL light-emitting device was observed under a microscope. As a result, occurrence or growth of a dark spot having a diameter equal to or more than 50 μm was not found.

### Example 3

In the present example, an organic EL light-emitting device having a structure shown in FIG. 1 was made. That is, a hygroscopic member was made of a solid hygroscopic material. Further, a moisture permeable member was provided, the moisture permeable member being an empty space formed in a space.

In the present example, an organic EL element was formed on a first substrate by use of a method and a condition same as those of the example 1.

The first substrate provided with the organic EL element was placed under an argon gas atmosphere, and the following steps were performed. First, the organic EL element disposed on the first substrate was disposed so as to face the second substrate. Next, UV curable epoxy resin seal material (available from Panasonic Corporation) was applied so as to cover a whole outer surface of the organic EL element, and cured by UV-irradiation, and thereby a protection layer having a thickness of 5 μm was formed. Thereafter, a solid hygroscopic material was applied so as to cover a whole outer surface of the protection layer, and cured by UV-irradiation, and thereby a hygroscopic member was formed. The solid hygroscopic material was prepared by adding calcium oxide (available from Kojundo Chemical Laboratory Co., Ltd.) to UV curable epoxy resin seal material (available from Panasonic Corporation) such that a percentage of calcium oxide be 30 mass percent. Further, epoxy resin (available from Nagase ChemteX Corporation) was put in a dot pattern so as to form contact prevention members each having a height equal to or less than 100 μm. Then, epoxy resin (available from Nagase ChemteX Corporation) was applied to a periphery of the first substrate by a dispense method in such a way that epoxy resin was not contact with the organic EL element, and thereby sealing members each having a height of 200 μm were formed. In this state, the first substrate and the second substrate were moved closer to each other until the contact prevention members reached the second substrate. Further, the contact prevention members were bonded to the second substrate. Thereafter, the first substrate 2a and the second substrate were bonded to each other by the seal material, and thereby the organic EL light-emitting device having a structure shown in FIG. 1 was made.

As is the case with the example 1, after leaving the organic EL light-emitting device in a constant temperature and humidity chamber under a temperature of 50° C. and a humidity of 95% RH for one thousand hours, a light-emitting state of the organic EL light-emitting device was observed under a microscope. As a result, occurrence or growth of a dark spot having a diameter equal to or more than 50 μm was not found.

### Example 4

In the present example, an organic EL light-emitting device having a structure shown in FIG. 4 was made. That is, a hygroscopic member was made of a solid hygroscopic material. Further, a moisture permeable member was made of a moisture permeable material having moisture permeability.

The present example is different from the example 1 in that UV curable polyurethane resin (available from Panasonic Corporation) having moisture permeability of 1500 g/m^{2·} 24 hour was applied as the moisture permeable material so as to cover a whole outer surface of the hygroscopic member, and thereby a hygroscopic member was formed.

Except for this point, the organic EL light-emitting device was obtained by use of a method and a condition same as those of the example 1.

As is the case with the example 1, after leaving the organic EL light-emitting device in a constant temperature and humidity chamber under a temperature of 50° C. and a humidity of 95% RH for one thousand hours, a light-emitting state of the organic EL light-emitting device was observed under a microscope. As a result, occurrence or growth of a dark spot having a diameter equal to or more than 50 μm was not found.

### Example 5

In the present example, an organic EL light-emitting device having a structure shown in FIG. 5 was made. That is, a hygroscopic member was made of a solid hygroscopic material. Further, a moisture permeable member was made of a moisture permeable material 9 having moisture permeability. Additionally, an inorganic film covering a whole outer surface of the moisture permeable member was formed.

The present embodiment is different from the example 4 in that a silicon nitride film was formed on the moisture permeable member by use of silane and nitrogen as raw material gas by a plasma chemical vapor deposition method, and an inorganic film having a thickness of 3.0 μm was formed so as to cover a whole outer surface of the moisture permeable member.

Except for this point, the organic EL light-emitting device 1a was obtained by use of a method and a condition same as those of the example 4.

As is the case with the example 4, after leaving the organic EL light-emitting device in a constant temperature and humidity chamber under a temperature of 50° C. and a humidity of 95% RH for one thousand hours, a light-emitting state of the organic EL light-emitting device was observed under a microscope. As a result, a tendency to cause occurrence or growth of dark spots other than early-existing dark spots was not found.

### Comparative Example 1

An organic EL element was formed on a first substrate by use of a method and a condition same as those of the example 1.

The organic EL element disposed on the first substrate was disposed so as to face the second substrate. Next, UV curable epoxy resin seal material (available from Panasonic Corporation) was applied so as to cover a whole outer surface of the organic EL element, and cured by UV-irradiation, and thereby a protection layer having a thickness of 5 μm was formed. Further, UV curable epoxy resin seal material (available from Panasonic Corporation) was applied so as to cover a whole outer surface of a protection layer, and the second substrate was firmly attached to the epoxy resin seal material from above. Thereafter, the epoxy resin sealing member was cured by UV-irradiation directed toward the second substrate from above, and thereby the organic EL light-emitting device was made.

As is the case with the example 1, after leaving the organic EL light-emitting device in a constant temperature and a humidity chamber under a temperature of 50° C. and humidity of 95% RH for one thousand hours, a light-emitting state of the organic EL light-emitting device was observed under a microscope. As a result, occurrence of many dark spots each having a diameter equal to or more than 50 μm and growth thereof were found.

1-19. (canceled)

20. An organic EL light-emitting device, comprising:
a first substrate;
an organic EL element disposed on the first substrate;
a second substrate disposed so as to face the first substrate with the organic EL element in-between; and
a sealing member disposed between the first substrate and the second substrate so as to surround the organic EL element, and
further comprising a protection layer, a hygroscopic member, a contact prevention member, and a moisture permeable member which are disposed within a space enclosed by the first substrate, the second substrate and the sealing member,
the protection layer for covering the organic EL element,
the hygroscopic member for covering the protection layer and absorbing moisture within the space,
the contact prevention member for preventing contact between the organic EL element and the second substrate, and
the moisture permeable member being in contact with the hygroscopic member and the contact prevention member and allowing moisture within the space to permeate.

21. The organic EL light-emitting device according to claim 20, further comprising a filling layer disposed within the space,
the filling layer including the contact prevention member and the moisture permeable member, and
the moisture permeable member being formed inside the filling layer to have at least one exposed surface facing the sealing member.

22. The organic EL light-emitting device according to claim 21, wherein
the moisture permeable member has a plurality of the exposed surface.

23. The organic EL light-emitting device according to claim 21, wherein
the moisture permeable member is a void formed inside the filling layer.

24. The organic EL light-emitting device according to claim 21,
the moisture permeable member is made of material having moisture permeability.

25. The organic EL light-emitting device according to claim 21, wherein
the hygroscopic member is disposed inside the moisture permeable member.

26. The organic EL light-emitting device according to claim 21, wherein
the contact prevention member contains hygroscopic material so as to double as the hygroscopic member.

27. The organic EL light-emitting device according to claim 21, wherein
the filling layer has a sea-island structure in which the moisture permeable member and the contact prevention member are arranged so that the moisture permeable member and the contact prevention member resemble sea and an island respectively in a plan view of the filling layer.

28. The organic EL light-emitting device according to claim 20, wherein
the protection layer becomes thicker toward a periphery than at a center of the organic EL element in a plan view of the organic EL element.

29. The organic EL light-emitting device according to claim 20, wherein
the protection layer contains hygroscopic material so as to double as the hygroscopic member.

30. The organic EL light-emitting device according to claim 20, wherein
the hygroscopic member is made of powder having a hygroscopic property.

31. The organic EL light-emitting device according to claim 20, wherein
the hygroscopic member is made of solid hygroscopic material having a hygroscopic property.

32. The organic EL light-emitting device according to claim 20, wherein
the moisture permeable member is an empty space formed in the space.

33. The organic EL light-emitting device according to claim 20, wherein
the moisture permeable member is made of material having moisture permeability

34. The organic EL light-emitting device according to claim 33, wherein
the hygroscopic member is covered with the moisture permeable member, and
the organic EL light-emitting device further comprises an inorganic film covering the moisture permeable member.

35. The organic EL light-emitting device according to claim 20, wherein
the contact prevention member is made of material same as material of the sealing member.

36. The organic EL light-emitting device according to claim 20, wherein:
the organic EL element includes an electrode facing the second substrate; and
the contact prevention member is conductive and is in contact with the electrode.

37. The organic EL light-emitting device according to claim 36, further comprising a conductive layer disposed on a surface of the second substrate facing the first substrate,
the contact prevention member being in contact with the conductive layer so as to electrically interconnect the electrode and the conductive layer.

38. An illumination device, comprising:
the organic EL light-emitting device according to claim 20; and
a device body to hold the organic EL light-emitting device.
